(19) United States
(12) Patent Application Publication
(10) Pub. No.: US 2005/0225365 A1
(43) Pub. Date: Oct. 13, 2005

(54) Electronic circuits

(76) Inventor: John Wood, Santa Cruz, CA (US)

Correspondence Address: DECHERT LLP, P.O. BOX 10004, PALO ALTO, CA, 94303, US

(21) Appl. No.: 10/504,559

(22) PCT Filed: Feb. 14, 2003
(86) PCT No.: PCT/GB03/00719

§ 371 Date: May 5, 2005

(30) Foreign Application Priority Data
Feb. 15, 2002 (GB) 0203605.1
Jun. 6, 2002 (GB) 0212869.2
Jun. 7, 2002 (GB) 0214850.0
Aug. 14, 2002 (GB) 0218834.0
Nov. 6, 2002 (GB) 02-022814.3

(51) Int. Cl. H03L 7/00

(52) U.S. Cl. 327/141

(57) ABSTRACT

A method of synchronizing a circuit comprising the steps of synchronising the circuit globally using a high-frequency clock signal, further synchronising at multiple lower frequencies by cooperative short-range state machines clocked by the high-frequency clock, and synchronising the state machines to each other by exchanging rollover signals between them.

The represent invention relates to developments pertaining to the fields of endeavour of the applicants own earlier International application no WO 01/89088, U.S. application Ser. No. 09/529,076 (national phase of PCT/GB00/00175), U.S. patent application Ser. No. 10/167,639 (divisional of U.S. Ser. No. 09/529,076), U.S. patent application Ser. No. 10/167,200 (continuation in part of U.S. Ser. No. 09/529,076), as well as that of internation application no PCT/GB2002/005514, the disclosure of all of which are incorporated herein by reference.

Further explicitly incorporated herein is the contents of the hereinafter reference UK patent application, the disclosure of which forms part of the present application a dn the inventions disclosed herein.

British Application No 0203605.1

The figures referenced below are those shown on sheets 1/53 to 17/53 of the drawings of the present application.

Hierarchical Clocking System.

Frequency Division/Pulse Latching/Adiabatic Systems

This scheme is designed to enable the Rotary Clocking Architecture to support legacy low-speed clock network topologies while allowing RTWO direct high-speed low-power clocking to be inserted for newly designed blocks.

Also assists in integrating SOC designs where multiple clock frequencies and clock phases are required.

Methods of achieving lower frequency-divided energy-efficient ‘adiabatic’ clocks from RTWO with special waveshape and phasing features are also described.

Note:—Throughout the text, assumption is made that there is either a control program, built into the VLSI device or else ofd chip hardware which is able to load and read the various shift registers and data registers—either serially or parallel. Methods to do this are widely known and standard

This application's background material is within, patent application PCT/GB00/00175 which is hereby included complete by reference.

General Idea:

Distribute RTWO at overclock frequency. This clock e.g. 10 GHz provides anti-phase clock edges at each % cycle e.g. 50 pS for 10 GHz clock (100 PS cycle). The full-speed clock is suitable for many application directly (high speed ALU, SERDES I/O ports).
Centrally located FLL (Frequency locked loop) to control the master ‘overclock’.—preferable to a Phase locked Loop.
Features:
   Coarse control (Frequency division—digital)
   Medium control (Switched Capacitor—digital)
   Fine control (Varactor—analogue)
Advantages over PLL
   Much more stable loop
   Lower power
   Lower area
   Higher speed
   Better stabilty (Jitter, Skew)
   Phase locking between multiple-frequencies
Phase locking is provided by RTWO inherent phase lock mechanisms (2 types: junction locking (inter-chip), delay-matched links (intea-chip).—works on the principle that if frequencies are locked, phase locking is simple matter of getting the “externally phase indifferent” rotating waves synchronised.
Use the ‘overclock’ to produce not just frequency divided but arbitrary waveshapes, phase-aligned to the reference clock for various applications.
   Legacy UO clocks—e.g. Pulse clocks
   Low frequency clocks for Global (e.g. Cache, long range parallel busses)
Allow replacement for active “deskew” mechanism.
Digitally controlled advance/retard phasing.—Eliminate cross-conduction current spikes.
Arbitrary repetitive waveform—High/Low periods, fractional N, possible.
Gives all features required of high-end processors including test clocks, etc.
Gives high-speed phased locked peripheral clocks for SERDES (Serial/Deserial).—Local high-speed clocking for ALU etc, from main clock.
   Topology.

Previous descriptions of RTWO structures have extensively used distributed components such as back-back inverters, switched capacitors, varactors etc located around the RTWO transmission-line path for frequency control, rotation direction bias etc.

In this application, these pieces are brought into a modular architecture alongside Waveshape generation components in what we refer to as “Binary Waveshaping Blocks” (BWBs). The architecture makes RTWO fit into a wide range of current VLSI synchronous clocking methodologies used in industry today without any change in underlying methodology.

There are inherent advantages in using RTWO waves directly in 2-phase non-ovelapping latching style which are not fully realised by this approach, and it is anticipated that a mix of the pure RTWO clock for new components and hierarchical RTWO clocking will be the best comprimise in a multi-frequency environment.

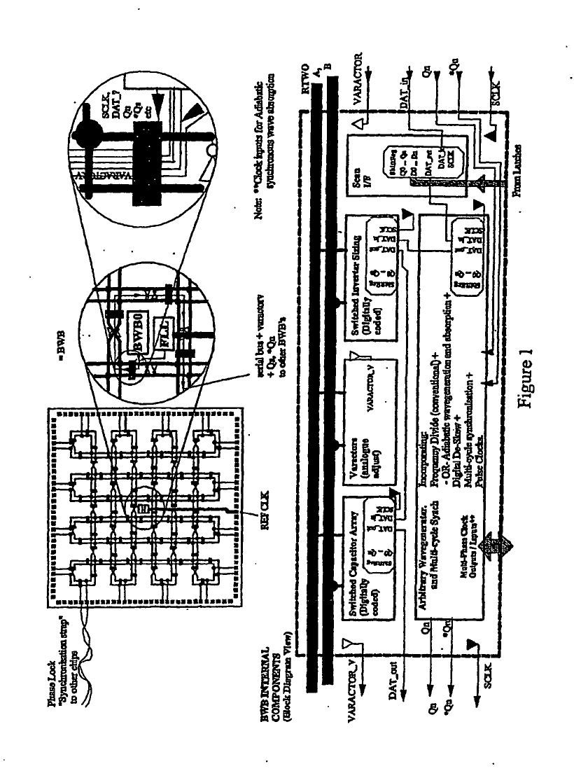

FIG. 1—Architecture.

Representative VLSI chip is shown with RTWO transmisson-lines and inverters evident
REFCLK input:—will be used to get the on-chip RTWO system synchronised precisely to an external reference frequency supplied on this pin.
Phase lock “Synchronisation strap” point is show on left side. These have been described in previous application and allow phase locking between RTWO chips by hard-locking. [The alternative method of PLL type alignment has not been dismissed as another solution]

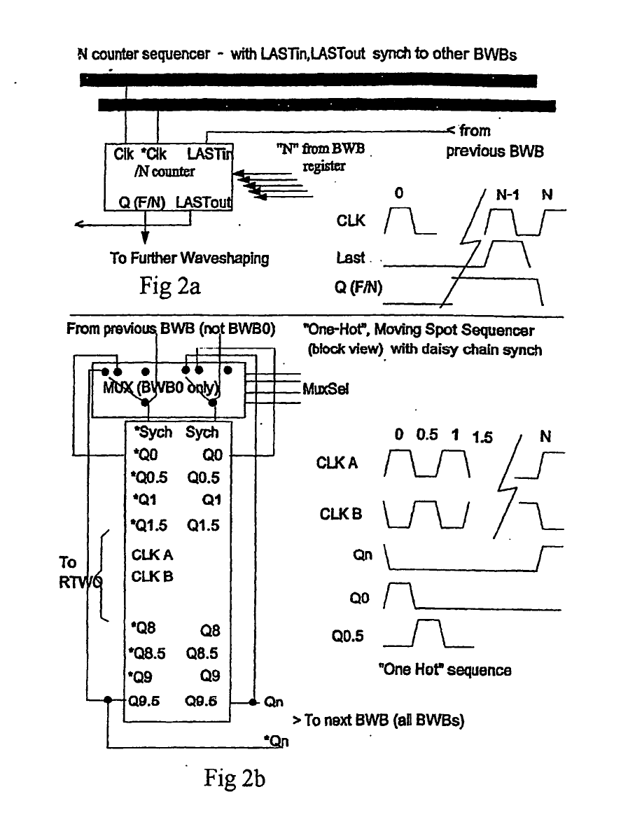

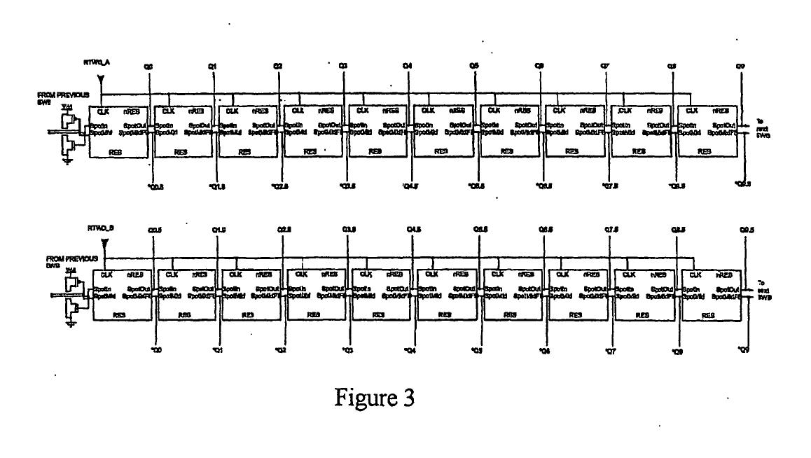

In the centre of the chip, two blocks are shown.
BWBO
   This is the primary “Binary Waveshaping Block” for the chip.
   It supplies the source of the Qn and *Qn Multi-cycle synchronisation signals (see further below and FIG. 2)
FILL
   Frequency-locked Loop.
   This circuit ensures that the main RTWO operating frequency of the chip is closed-loop controlled to be exactly some multiple of the input REF CLK which could come from external system standard e.g. Quartz Crytal.
      Essentially, if the RTWO frequency is higher than (REF_CLK xX) it is reduced by Varactor or Switched capacitor control until it is precisely locked in Frequency. Detailed operation is described further below
Absent: PLL
   In theory, frequency and phase can be controlled to an external reference using a PLL and Phase-Frequency comparator. In practice, there is so much uncertainly in phase on the REF_CLK especially as it travels into and then across the chip, that it is useless as a phase reference.
      Phase locking between the RTWO chip and an external phase can be achieved with hard wire locking (described in previous applications) -OR- by using a implicit phasing information e.g. By detecting the edges of an incoming NRZ data stream and adjusting the phase of the RTWO rings (via Varactor control) until the data is sampled synchronously. [TBD]
      Multiple Global, Frequency-Divided Clocks:

The object of this architecture is to produce clocks related in frequency and phase to each other all around the chip. The main RTWO clocking array gives precise phase relationships between all points on the chip for 360 degrees of phase due to pulse combination mechanism on transmission-line—see JSSC paper.

Where multi-cycle events are to be synchronised (e.g. To generate a clock which is 1/10 of the main RTWO frequency), not only is a sequential state machine required to perform the sequencing over multi-cycles, but since this /N clock should be phase-aligned with other /N clocks on the chip, there has to be some global synchronisation signal to keep the states of the state machines in sych, to they all go through state 0 together.

An obvious method is to distribute a global ‘synch’ wire around the chip for every derived clock—but this wire would need to be designed to travel the entire chip with precise timing with skew a fraction of the master RTWO clock cycle. This is just as difficult a problem as generating a conventional H-tree clock and is infeasible.

Instead, we propose to have each of the state-machines in the BWB blocks signal to it's neighbour when it has completed its sequence prior to looping. The signalling distance is therefore short. In effect, each BWB signals to it's neighbour that it is about going to ‘loop’ to state 0 in the next RTWO cycle (or ½ cycle), which the receiving BWB will take as a command to go to state 0 on it's next RTWO clock edge ensuring eventually that all BWB states come into sych across the chip.

(Power consumption due to this is low—the frequency is Nx less than RTWO frequency and the load capacitance is just a pair of reciever gates at each BWB)

A drawback of this approach is that it takes Nx (number of BWBs) RTWO clock cycles before the whole chip has it's Multi-cycle state machines synchronised

To mitigate this, possible to “fan-out” from the primary BWB to drive say 4 near-neighbours, from each BWB.

The upshot of all this logic is that there is a “Global” i.e. Chip-wide sequence (or RTWO cycle) number available, which allows for logic which responds sychronously over the whole chip at rates lower than fRTWO.

BWB Circuitry Details:

Qn and *Qn outputs from the sequencer/state machine perform this function in Fig L. And can be seen on the insets daisy-chaining between BWB blocks.

Qn and *Qn are the true and complement of the last-state of the loop within the Sequencer.

FIG. 2 shows waveforms of two possible sequencer state machine. The machine can be as simple as a /N counter with output logic to generate the last state (i.e. N−1), or could be a “One-Hot” AKA “Moving Spot” state machine where the last state is on an explicit output.

FIG. 2a Illustrates a /N counter with a “LASTin” input and “LASTout” output which allows it to be synchronised by previous /N counters in BWBs, and allows it to synchronise the next /N counter in following BWB using it's LASTout.

LASTout goes high on the count just before the /N counter returns to zero internally. LASTin is a registered input which when high, forces the counter to go to count 0 on its next count.

Sequencing can be used to generate arbitrary waveforms. In the simplest case, a /N counter is a sequencer which gives a 0->1->0 output sequence when a total of N clock pulses are given to it.

Arbitrary Waveforming

A more general purpose clock waveform generator can be made using a N-state sequencer (“One-Hot encoder” or “Moving Spot”) coupled with gating and an output buffer.

This has a similar multi-cycle synchronisation system to the /N counter and has been discussed previously, it used *SYNC and SYNC inputs to receive a *Qn and Qn input from previous stage and outputs it's own *Qn and Qn to the next stage.

NOTE:—Synchronisation is an N-clock sychronisation, there is still a within-cycle phase offset depending on the BWB block's location on the RTWO line.

In FIG. 2b shows block diagram and timing sequence of “Moving Spot” based sequencer. The Primary BWB (BWBO) is different from the other BWBs because it generates it's own feedback from its output via a MUX.

Selection on the MUX allows variation on the length of the sequence programatically if desired [when connected to an on-chip or ofd chip microprocessor].

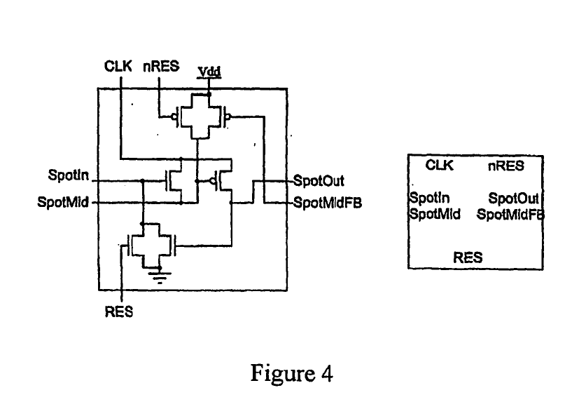

One method of making this Moving spot register is with shift register elements. Another method is to use dedicated logic, such as shown in FIG. 3. Illustrating a dual “Moving Spot” generator to get true and invert One-hot encoding signals on outputs QO . . . Q9.5. This example gives a 20 bit sequence, and loads the RTWO lines A and B symetrically. The state advances on each ½ cycle (i.e. Rotation) of the RTWO clock signal. FIG. 4 Shows the internal components of a single-bit “Moving Spot” element used to make up FIG. 3 Strips.

*SYNC and SYNC equate to the signals on the left side of the drawing, Qn and *Qn equate to the signals Q9.5 and *Q9.5 on the right.

Wavegenerator using the “Moving Spot” sequences are more flexible than /N counters.

An arbitrary waveform with high and low times defined digitally with resolution of % RTWO clock period are available.

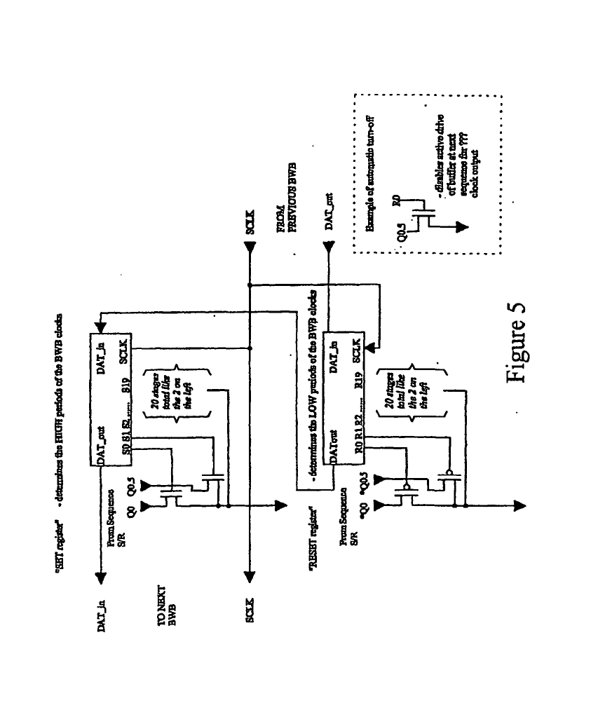

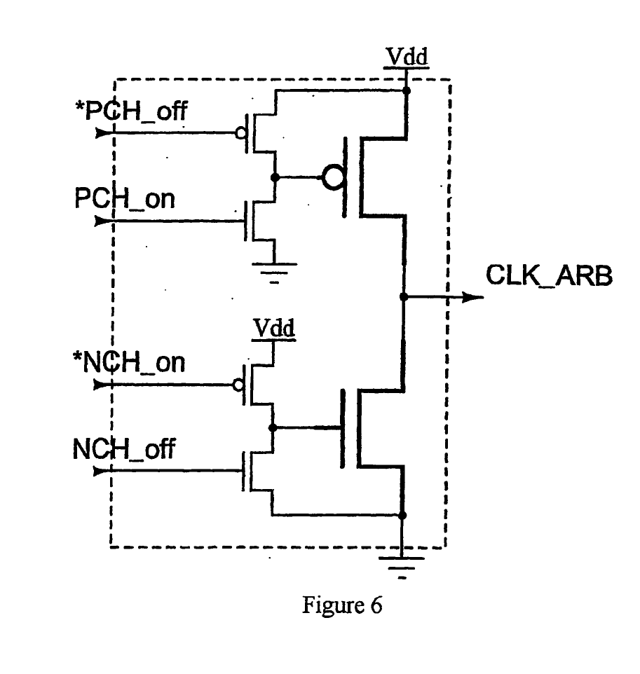

FIG. 5 Gives a circuit which interfaces to the Moving Spot generator outputs to digitally set the “On” and “off” times of an output clock waveform (CLK_ARB) in terms of the high-resolution RTWO 1/2 period. Via the buffer shown in FIG. 6

A “1” in the SET register will turn on the CLK_ARB output at that sequence in the Movingspot sequence. Similarly a “0” in the RESET register turns off the output at that time in the sequence. The CLK_ARB can transition once per RTWO period at maximum and once per RTWOperod/Nsequence length,
minimum giving a frequency (two transistions) range of FRTWO/10 for a 20 spot sequencer. The flexibility of the CLK ARB comes from the programability.
   Frequency can be adjusted by setting the global sequence numbers where state changes.
   High time, low time can be set independently—facilitates pulse-clocks.
   Deskew—programable global sequence numbers of the commencement of the high-period and low can programmed individually for each clock in the BWB
   effectively allows programable de-skew to resolution of % RTWO period (e.g. 50 pS @10 GHz RTWO frequency).
   Gating—possible to gate clock off
   Strobes and other specific, non-standatd synch signals can be made and will be globally synchronous.

More than one CLK_ARB can be produced locally to each BWB, the SET and RESET and buffer circuitry have to be reproduced for each independent clock produced.

BWB sequences can be any length required, depends on the minium frequency required, Not all BWBs need to have the same sequence length (can use OR-gate to pass out SYNCH pulses at the intermediate point when a 20-long sequencer is linked to a 10-long sequencer.)

Using the BWB, a very close proximity to true-single phase clocking can be approximated, at the reduced-frequency clock rates for legacy applications.

The arbitrary (reconstructed) waveform edges are syncronous to the local arrival of the RTWO wave. For a conventional, regular RTWO loop array, with 360 degrees requiring 2 rotation times of an edge on the RTWO (180 degrees per rotation), the highest level of nonsynchronisity between the furthest two points on a loop (diagonally opposite corners—half a rotation away from each other) i.e. 90 degrees out (1 cycle) at the Foverclock Nominating a single point on the RTWO to be “Phase angle Zero”; you find that by using either *CLK or CLK line, any other point cannot be greater than +1-90 degrees in phase error. (e.g. Moving from +90 to +95° point, you can use the other phase and this +95 degrees becomes −85 degrees)

At IOGM, this is +1-25 pS, representing +1-Z.5% of a 1 GHz “virtual single-phase” clock well withing the 10% typical skew budget.

The error is stable and calculable and could be accounted for by adding time to the minimum delay to prevent any race conditons. The fact that the phase is known makes it much easier to deal with than fitter which is random variation of skew.

BWB are synchronised to each other by an interwiring line from the Qn output of one stage feeding the *SYNC SYNCH inputs of the next stage in a daisy chain fashion.

Controlled clock gating and orderly shutdown involves de-asserting the Qn*Qn from the primary BWB.

In a reverse process to the startup, the BWBs will stop in sequence (since their SYNCH pulses stop).

Alternatively, individual BWBs can have their sequence data changed, allowing new waveshapes, phasing, frequency changes to be implemented.

Speed changing involves loading new data into the SEQ.CTRL registers, which get updated prior to count#0 or any other count code suitable.

Array storage for different sequence data to bo loaded in after each sequence (effectively lengthening the sequence).

BWB and sequencers can also be used to make special clocks e.g. Handshaking signals, strobes etc.

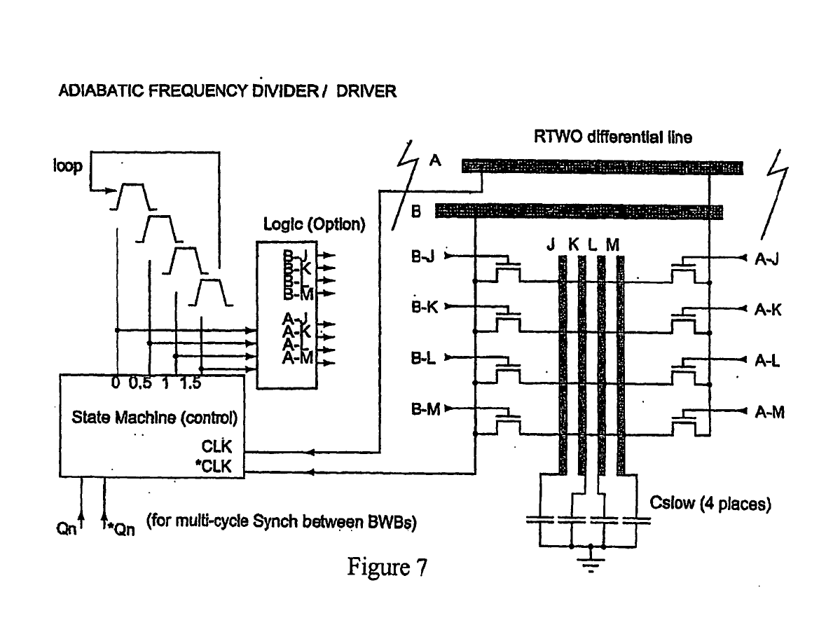

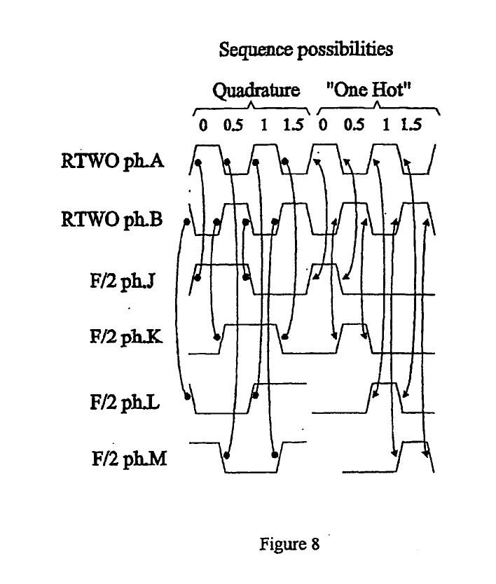

Adiabatic Clock Generation—FIG. 7, FIG. 8 (Replaces FIG. 5 and FIG. 6)

RTWO signals are energy conserving, because electric (capacitive) and magnetic (inductive) energy is continously re-used as a travelling wave travels around a closed path. RTWO loops tend to produce very high frequencies when applied on VLSI dimensions.

To support legacy interfaces and clock frequencies, Frequency division (i.e. dividing a clock frequency to produce another lower clock frequency) has been mentioned previously for RTWO.

Unfortunately, Conventional frequency dividers and buffers Ike those just described are not adiabatic, i.e. they dissipate energy in driving load capacitance.

This section describes the principle of Adiabatic frequency division. However, other options to slow RWTWO involve are possible.
making higher inductance values to slow the line down—increase load capacitance to slow line
“wrap” multiple loops of RTWO line around a region to extend the transmission-line length but maintain perimeter.

Adiabatic frequency divider outlined here gives another ‘slow-down’ option.

In a pulse transmission-line system such as RTWO, line current charges the distributed capacitances for a forward-travelling ‘edge’. It is possible to steer these currents to charge and discharge other capacitances at frequencies synchronously related in frequency to the main loop frequency and thus generate low frequency.

The RTWO line doesn't “know” the difference.

In practice this is difficult to achieve in an efficient manner on anything other than a very modern (0.18 u or less) CMOS process.

Principle.

The principle used is the observation (looking at FIG. 8) that a 2-phase clock of frequency F, can be split into (2*N) phases at frequency F/N.
Simple example would is splitting a 2-phase 4 GHZ clock into a 4-phase 2 GHz clock.
   Table 1, Switches Operating During Sequence.

Count Switches On during this cycle inital transition, *Optionally
O A-J,B-L, *A-M, *B-K
0.5 A-M,B-K, *A-L, *B-J
1 A-L,B-J, *A-K, *B-M
1.5 A-&B-M, CA-J, *B-L

Switches are controlled by the “One-Hot” state machine, similar to that described for the BWB units, but here just a 4-state machine.

*Optionally, Transistors above can be activated in the previous steady state (platau level) to allow for transistor turn-on time before the next edge occurs, and this means transistors are turned during a quiettime, with lower loss.

The unit labeled “Logic” incorporates simple gates to achieve the additional output gating required by the * items in the table above. Without this option, the outputs 0, 0.5 . . . 1.5 just drive directly one or more of the gates of the NMOS transistors for quadrature outputs.

There is no particular reason to adopt a quadrature signal sequence (Left hand side of FIG. 8) and any sequence of any number of phases can be generated. The only limitation is that (ideally) every edge of the RTWO clocks should be switched into the same capacitance each time.

A useful version is the “One Hot” clocking scheme shown on the right of the timing diagram. These clock signals produced at J,K,L,M are able to drive capacitance adiabatically i.e. not subject to CV\hat{ }2F power, although I\hat{ }2R power is lost in the ‘On’ resistance of the Mosfets and the RTWO transmission-line conductors.

In theory, Switching transistor gate capacitances can be adiabatically derived from any of the clocks, so this would not cause power wastage.

Effective Capacitance for the Main RTWO Line:

The capacitive load on each of the /2 frequency output phases is C slow (representing logic load capacitances) then the differential capacitance presented to the RTWO for the analysis of velocity and impedance is C_slow/2 because at any time, the RTWO (differentially) is charging two of the capacitors in series. RTWO line operates as normal, unaware of the ‘phase-splitting’ occuring at the adiabatic dividers (of which there can be any number located anywhere on the rings)—it just seems to drive capacitance as normal.
   Descriptions Above Consider the Driving of Locally Capacitive Loads.

Alternatively, or additionally, the clocks can drive other transmission-lines e.g. to drive a “one-hot” pulse-clock to a remote location.

In effect, a J,K,L or M clock acts as branch on the RTWO line energy and impedance-matching is required for low-reflection energy flow. (same condition applies as capacitance i.e. the RTWO line should see same impedance on each part of the sequence)

Recombination of Energy.

The Multiphase frequency-divided clocks are inherently bidirectional and can pass energy between JKLM and RTWOA,B in either direction.

Interestingly, the ‘remote-end’ of the JKLM tap transmission-line could be recombined back into another location of RTWO line using JKLM phase point at another BWB. Globally, the sequence number is synchronoys, and timing would be correct for the Mosfet switches to route the signal from either JKLM into the RTWO line. [Impedance matching, and timing considerations apply].

another use of JKL,M phasing scheme shown here would be to (synchronise) between two-phase F RTWO loops and 4-phase loops (Twn wraps around a perimeter—the alternative method) ½ F loops.—energy could go between them and synch them together.)

Scan Test.

A Scan-Test block is shown within the BWB block diagram (FIG. 1b). The standard JTAG boundry scan shift register system may be compatible with the proposed global serial data interface, permitting scan chain logic to share the same DAT in/out, SCLK bus as the other BWB components.

FLL—Frequency-Locked-Loop

To synchronise arrays of RTWO chips without PLL and all its problems of jitter, bandwidth and area.

Only a single FLL controller required per VLSI chip.

Previous applications described how passive transmission-line links between chips are able to synchronise same-frequency RTWOs on them together.

Weak (ie. >>Zring) coherent links between chips will pull together two chips if the difference in frequency of the rings is small.
Getting the initial frequency difference small is the remaining issue.
   Frequency Locking is One Good Method

Use a Frequency-locked-loop—a very easy device to make from an up/down counter—or could use a high precision charge pump circuit
REF_CLK can come from an external low-frequency F reference—F_int can come from the RTWO clock /N
phase is unimportant, so edge rate etc, delays don't matter, you dont try and control a phase, just F
Control the RTWO frequency using switched caps or varactor
Use the INNERMOST (centrally shown in FIG. 1) rtwo ring (furthest away from the periphery where the frquency locking connections are) to measure and lock the RTWO frequency.

This ring will be more-or-less independent of effects of frequency on non-synchrous signals injected into the remote rings.
With the innermost rings of multiple RTWO chips operating at identical frequencies, there is absolutely no preferred relative phase to the outside world (it is rotating after all), it is easy therefore to synchronise phase it with an imposed, signal—will lose energy from rotation until fully in synch.
closer it is to synch, less energy is lost—Precautions
Weak linkage is subject to slippage—RTWO has to be made very stable unless lots of linkages are present.

NOTE:—the above only works at one frequency—determined by the off chip transmission-line time.—to fix this, can use external RTWO amp type devices to trim those lines also—but gets tricky to coordinate the whole thing.

FLL System Details

Two (of Many Possible) Methods. (1)

Dual charge pump—one pumping current in, other pumping it out.—Calibration—drive both pumps with the same clock, and trim until no output—needs a mux
Up/Down counter.

Reference: “Phaselock Loops for DC Motor Speed Control” Dana. F. Geiger, Wiley, 1981 pp v, pp 77-92

Method 1

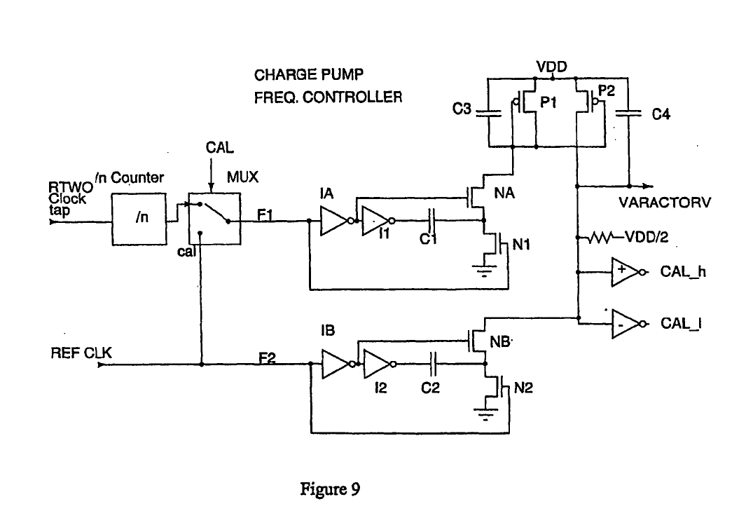

Charge Pump Frequency Controller. (Chargepump fcomp.ps) FIG. 9.

Purpose:

To lock RTWO frequency to some multiple of an external reference frequency.

Compares two frequencies and output a control signal proportional to the difference between the frequencies to control varactor (or switched capacitors) applied to the RTWO line to modulate the rotation time, hence frequency.

Not a Phase-Locked Loop

/N counter is used to dividive down RTWO frequency to a lower frequency for matching to a low speed external reference F. Frequency comparision is done at low frequency to ease the distribution of the reference clock which is difficult to control if full-speed reference.

Inverters: IA, I1, IB, 12—CMOS inverters (Pch/Nch)—Powered from supply VDD, 0 v

Function:—each cycle of F1 frequency a charge equal to C1*VDD is pumped to current mirror P1.—each cycle of F2 frequency a charge equal to C2*VDD is pumped to current mirror P2.

When frequencies are equal, the current (charge*frequency) of the above two currents will be equal (for C1=C2).

In this case, the matched transistors P1,P2 will force zero current to the P2 drain, keeping voltage “VARACTORV” steady.

A mismatch in frequency causes mismatch in P1,P2 currents, and “VARACTORV” will slew in a direction and magnitude proporotional to the mismatch in frequencies.

This adjusts the varactor voltage, hence RTWO frequency to restore RTWO frequency to that of a multiple of the lowspeed reference elk.

This is an in-princple description, applicable to other charge-pump schemes known in the art.

Calibration is possbe in the above circuit by routing the F1 and F2 inputs to the same REF clock using the MUM. In this condition, there should be no output drift or VARACTORV from the bias point VDD/2 volts. CAL h and CAL l are inverters with modified thresholds which can be read by a state machine to determine if the frequency comparator is accurate. Self-Trimming is possible by many means e.g. changing (binary wieghting) of C1 or C2 capacitors using known switched-capacitor means—or by injecting a programable offset current into either P1 or P2 drain current. Accuracy of 0.1% can be expected and this is enough to allow for hard-wired phase locking over passive links for RTWOs (described in earlier patent applications).

Method 2

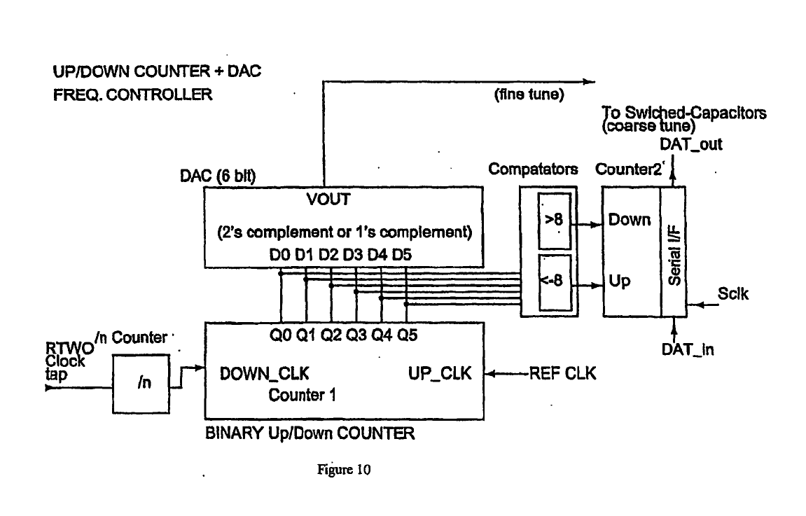

Digital Counter System. (counter_fcomp.ps) FIG. 10.

Reference: “Phaselock Loops for DC Motor Speed Control” Dana. F. Geiger, Wiley, 1981 pp v, pp 77-92

The reference cited above outlined a practical approach to DC motor speed control using a digital up/down counter to compare frequencies. The approach of controlling Frequency as the primary loop variable gives a much more stable loop than Phase/Frequency detector systems which have marginal stability

The operation is straightforward. design a binary counter which has an UP and and DOWN clock. The UP clock is fed from frequency F1, and the DOWN clock is fed from F2.

When frequencies match, the counter gets net zero increment or decrement of it's count value and alternates about the same value.

Addition of a DAC and a control loop (in this case Varactor control of the RTWO frequency) forces the counter to jitter around value 0.

An 8-bit counter using 2's complement notation gives signals of +127 to −128 which the DAC scales to an output current to drive VARACTORV directly or via an analogue integrator.

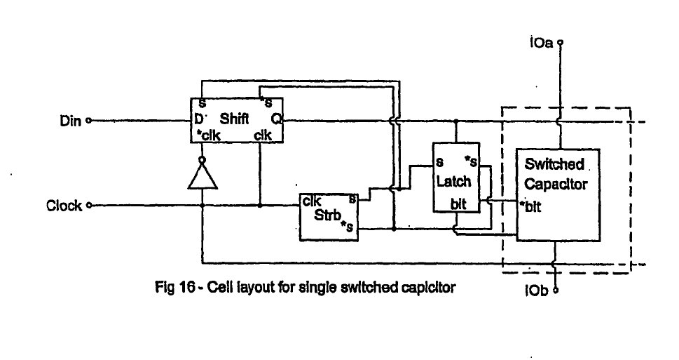

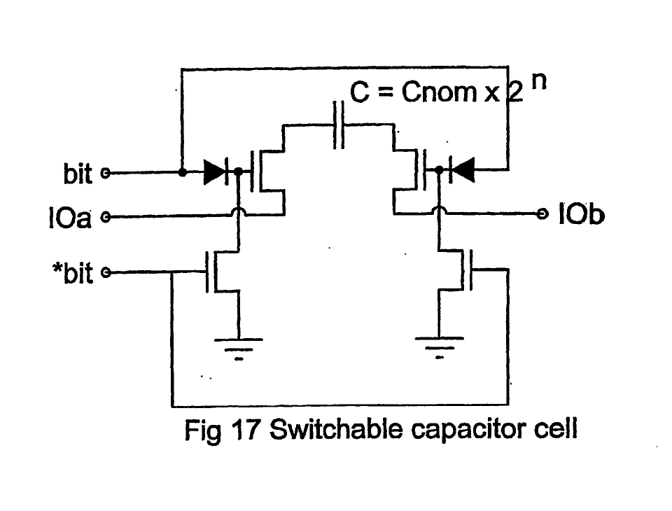

Varactor trimming can achieve +/−20% frequency variation, but larger tuning range can be achieved with switched capacitors [Sec FIG. 16]. The addition of the digital comparator block and Counter2 can supplement varactor control when it alone is not sufficient to achieve frequency lock. The operation of Counter2 controls the Switched-Capacitor arrays distributed around the chip—it's value is distributed to all BWB blocks using the shift register mechansim.

The design of the binary Comparators makes the Counter2 increment or decrement whenever the error counter (Counter1) is out by more than 8 or −8 (chosen arbitratily) respectively. This selects larger or smaller binary weighted capacitanced added to the RTWO line to bring the frequency into a range where Varactor fine-tune control can fully close the loop.

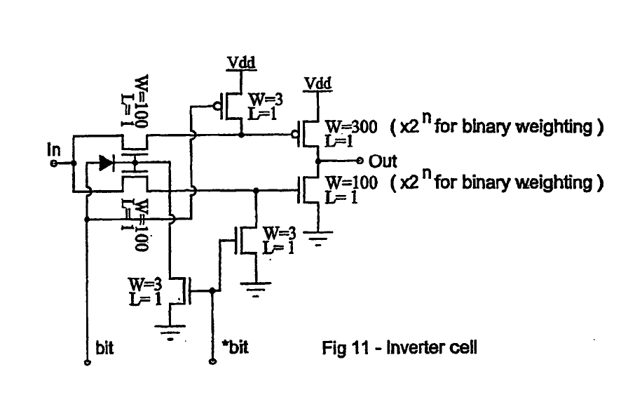

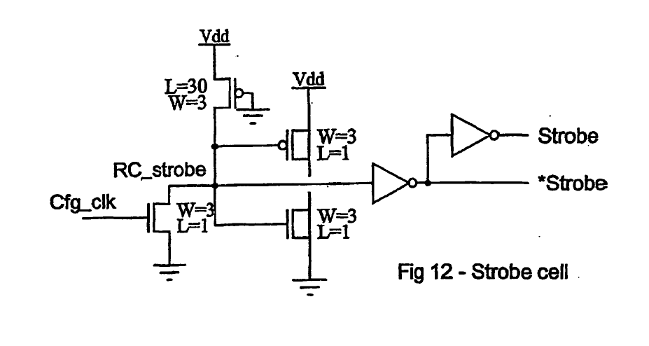

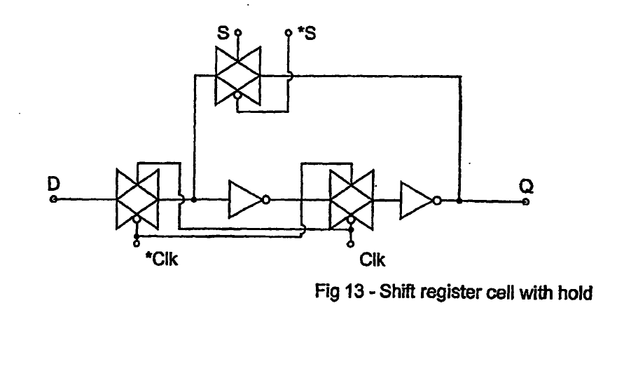

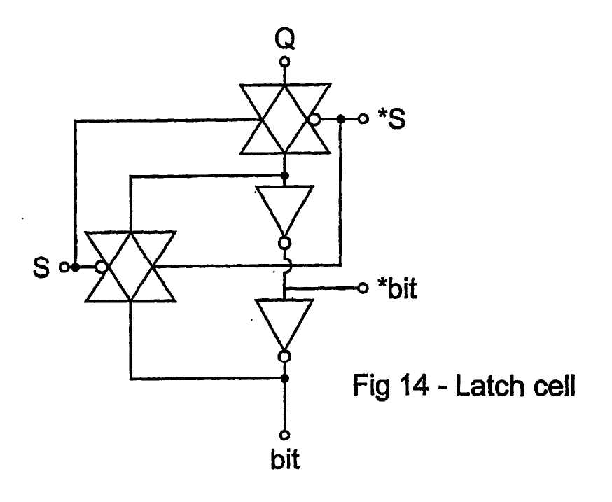

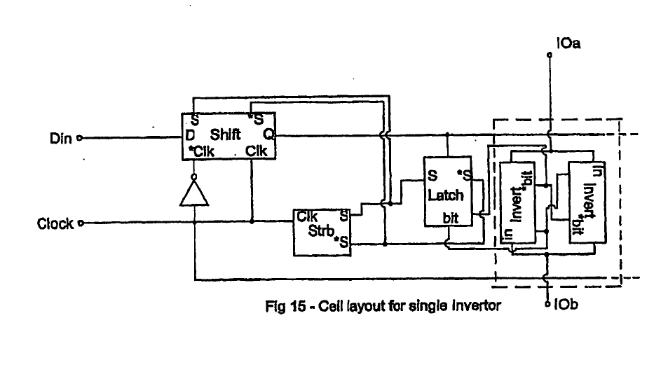

FIGS. 11 to 16 inclusive show component details of blocks referred to in passing in the main text (see below for descriptions).
file list.
TurboCad:
hierO.tcw—main block diagram
[
hier2.tcw—mechanism for digitally setting the “on” time and “off” time for arbitrary (non-adiabatic) clock generator (to feed to the buffer)
Xcircuit:
adiab_{—}1_sch.ps—Components of adiabatic 4-phase generator (see also adiab_{—}1.sda)
buffer_block.ps—Non adiabatic CMOS buffer with individual inputs to control crosscondution
chargepump fcomp.ps—Charge-pump frequency comparison method.
counter_fcomp.ps—Digital up/down counter method of frequency comparison.
moving_spot_reg.ps—one method of making a “moving spot” register.
spntmove elem.ps—expansion of the basic moving spot element XA.ps
   Switched-size inverter cell (digitally controlled).
XB.ps—stobe cell (for automatic generation of stobe in absence of SCLK)
XC.ps—shift register (single bit)
XD.ps—latch cell (for holding shift-register values with Strobe).
XE.ps—Complete cell for digital sized RTWO inveter cell (back-back)
XF.ps—Complete cell for digially controlled Switched RTWO Capacitor
XG.ps—Switched capacitor (single bit).
Staroffice:
adiab_{—}1.sda—possible 4-phase clock signal sequences which can be generated adiabatically.
fdiv_{—}1.sda—picture of a /N counter block and a “Moving
   British Application No 0214850.0

The figures referenced below are those shown on sheets 18/53 to 20/53 of the drawings of the present application.

High performance dynamic clocked logic family for use with Rotary Clocking or other adiabatic clock source background material regarding Rotary clocking and RTWO, ROA is contained within patent application PCT/GB00/00175 which is hereby included complete by reference.

Background

Logic circuits on CMOS VLSI can be classed as either Static or Dynamic.

Static Logic:

Static logic gates are the norm. They use complementary devices—Nch's to give logic 0 output, Pchs to give logic 1 outputs. There is no requirement for a clock to perform the logic operation, but clocks ARE required for latches which capture and sequence the results of the logic operations.
FIG. 1a conventional static CMOS Nand gate [latches and clocks which are required elsewhere sre not shown]
   Dynamic Logic:

Dynamic circuits use only Nch devices in their evaluate paths and so are usually only able to output logic Os. The logic 1 values are established by using a Clock circuit to ‘precharge’ the output to 1 which initialises the output before the possibly −0 output.

The advantage of using only Nch devices is that they have between 2-3× better electron mobility and so give lower input capacitance for a given switching drive ability.

Dynamic, (or clocked logic as it is also known) has a long history.

Although largely displaced by CMOS (Pch & Nch) static logic, dynamic circuitry has a niche where maximum performance is the main requirement.

Many forms of dynamic logic have inherent storage and so often latches are not required in a dynamic logic system.

FIG. 1b conventional dynamic CMOS Nand gate whose output is precharged to VDD when CLK is low, and goes low only when CLK goes high and both logic inputs are also high (for the Nand function).

A further classification of logic circuits is adiabatic and non-adiabatic.

Non-Adiabatic:

These are the norm where the energy for logic evaluation and output comes from the power supply rails. Energy expended in charging the outputs and interconnect is wasted each time a logic transistion occurs, effectively it's just like charging up a tiny battery and then discharging it with a short circuit each and every cycle. Power is related to C*V\hat{ }2*F and at GHZ frequencies even a tiny capacitance causes massive power waste.

Adiabatic:

Energy for logic evaluation and output drive comes from a ‘reversible’ energy source and the charging of the capacitances involved in logic switching is done progressively by a voltage source (e.g. a sine-wave clock) which is always close to the instantaneous voltage on the capacitance being charged or discharged.

The gradual, or adiabatic charging results in recoverable energy transfer. Energy is just being moved around between logic circuitry/interconnect and the clock energy.

FIG. 1c is a potentially adiabatic logic gate because it is powered from an RTWO circuit which is an adiabatic voltage/charge source/dump.

In principe Rotary Clock can power any known Clock-powered logic circuit with greater speed and efficiency than sine wave or resonant circuits.

### DESCRIPTION OF INVENTION

Dynamic, Adiabatic, Rotary-Clock Logic Family.

Rationale:

Dynamic logic is the highest performance logic technique, Adiabatic logic has the lowest power consumption, Rotary Clock technogy is the highest performance adiabatic timing signal generator.

Combining these three attributes should give the best possible power/performance of any synchronous logic system and the rest of this description outlines such a logic family we are calling DARL (Dynamic, Adiabatic, Rotary-clock Logic family).

DARL logic circuits are sequenced and energised by Rotary Clock networks. Rotary Clocks have the unusual ability to drive considerable capacitance with a high frequency square wave without incurring CV\hat{ }2F power consumption due to an inherent recycling method.

DARL logic circuits extend this power-saving benefit to logic circuit evaluation and signal-interconnect capacitance driving. If this could be achieved in practice, there is the real possibility of eliminating most of the power consumption of a typical VLSI chip.

Losses are made up by the active circuitry on the RTWO lines which refreshes both the clock and the data interconnect losses.

Circuit Description.

FIG. 2 And/Nand—Gate Followed by Buffer/Inverter.

The underlying concept of this logic familiy is that the Rotary clock energy is routed adiabatically to the output capacitance by Nch transistors based on a logical combination of input signals. One or other of the outputs transitions with the Rotary clock wire giving a uniform capacitive loading as seen at the RTWO.

For a simple inverter/buffer, the CLK signal is routed to output Q if the inputs are logic 1, and routed to *Q if the inputs are logic 0.

True and Complement inputs and outputs are a feature of the logic family.

The main visible features of the circuitry for each gate are:—Input sampler or resistor
Nch transistors with intrinsic gate capacitance—Logic path 1
Logic path 2
Interconnect, or output capacitance.
Optional extra storage capacitance on the inputs after the sampler.

In the case of a resistor in lieu of a sampler, the gate-drive capacitance is not being driven fully adiabatically. To recover the small enery here would need a derivative phase [e.g. A quadrature phase from a 4-phase RTWOJ. It may not be worthwhile in practice since most of the load capacitance in modern chips is clock and interconnect capacitance.

Waveforms for DARL Buffer/Inverter [FIG. 3]

There are two phases of operation for each gate:

Sample/Evaluate (Logic Phase 1)

This state begings with CLK beginning its low-going edge.

Whichever logic path had previously propogaind a “1” will now have it's output returned to 0 because the logic path is still on (haven't yet sampled the new data), and so CLK is still connecting to the output—Note, it falls at the same rate as the clock since it is connecting to it—this ensures adiabatic discharging.
During CLK low plateau, both logic paths (1&2) sample the input signals from the previous stage which is currently propogating it's evaluation. This may alter the active logic path but since the outputs will already by at logic 0, they cannot change. Charge stored on the gates of the Nch represents the sample node. Additional capacitance could be added.
For gates with more than one transistor in each logic path, each will sample and the series or parallel path of the transistors constitues a logic function. Only one or other of the logic paths can be active.
the outputs Q and *Q will be at logic 0 (actively pulled to CLK voltage for one logic path, memory of Ov for the other logic path).
   Propogate (Logic Phase 2):
CLK going high represents the Propogate phase of the logic process.
Where a sampler is used on the inputs, it is turned off at this point to prevent the previous logic stage from removing the sampled signal (possibly this switch off is done by CLK*CLK or by another phase point from the RTWO or by a logical combination of phase points to get an exact timing window—see illustrations)
There will be ohmic path from CLK to either Q or *Q depending on which logic path evalutated. This ohmic path is maintained by the charge on the gates of the Nch transistors.
CLK going high therefore is coupled to either Q or *Q. The transition follows the RTWO clock line closely because it, is connected to it through some resistance from the Nch transistors.
Sizing of the Nch transistors is critical to making sure the charging/discharging is low-loss (adiabatic). Adiabatic charging/discharging is realised when there is very little phase lag between the RTWO clock and the output waveforms (low voltage over the resistance of the mosfets).

To create a logic pipeline alternating CLK and *CLK powered gates are placed in series. There are no race conditions since one state is sampling while the previous and next are propagating—logically this is very much like a classic 2-phase latch style which imposes it's own well-known constrains on feedback paths.

FIG. 2 illustrates this showing how the preceeding AND gate is driven from the opposite (typically) phase.

Phasing:

Rotary Clock is locally 2-phase with 360° “liquid” phase available globally. Advantage can be taken of the geographically variable phasing to improve timing. The 180 degree phasings in the simplest local case above is just an example. Sequentially connected DARL gates with less than or more than 180 degrees of phase separation on their clock sources can be useful. e.g. Time borrowing/stealing and for fractional-cycle offset synchronous repeaters.

Capacitances:

The Rotary Clock line sees a capacitance loading on each transiston. Either the Q or the *Q output is transistioned. There are three balancing requirements for ideal performance (Note that perfect matching is not required but waveshape distortion is likely when mismatches are >10%).

Balancing Condition 1:

Interconnect capacitances on Q and *Q for each gate should be equal on a per-gate basis (by padding if needed) to keep constant capacitance seen from either CLK or *CLK depending on the gate.
   Balancing Condition 2:
To operate differentially, CLK and *CLK should have matched capacitances. On average in any local area, the capacitances driven by CLK and those driven by *CLK should be matched.
   Balancing Condition 3:
At the long-range and global levels, balancing and impedance matching (kirchoff type) is performed as documented for RTWO line balancing since the logic appears as normal, fairly constant clock load capacitance.

The circuit just described is just one example of a circuit which steers rotary clock [or any uniflow transmission-line energy] selectively and in a balanced manner. The upshot is that Logic gates themselves, and the logic interconnect capacitance become just another part of the rotary clock capacitance. Software such as Rotary-Expert (REX) call design a suitable layout. [PCT/GB2002/005514 incorporated herein by reference].

This principle extends to driving any capacitive load, and could certainly drive DRAM SRAM or other memory decode lines in an adiabatic fashion.

RTWO Structures/Inductance Options.

Classic RTWO structures can be used with vias and multilayer interconnects to route down from the RTWO lines to the logic gating to provide the clocking. At higher frequencies, the vias themselves and the short-range interconnect become significantly inductive. It is then possible and sometimes important to treat these as part of the RTWO lines, or as RTWO lines in their own right, and move to the branch-and-combine flow matching algorithms during layout [re software patent] instead of just treating the logic gates as stub loadings on the main RTWO.

Sense Amps:

FIG. 2 also shows some cross-coupled Nch devices between the outputs and option for a push-pull sense amplifer. These can help to enforce a differential potential difference in the presence of noise, and can give a return current path for capacitively coupled signal in the non-driven logic path output.

Further Refinements on this are:

Nch/Pch back-back inverter version (shown).
Connecing common drain points to opposite clock line instead of to supplies.
   Device/Substrate Options:

SOI process is ideal vehicle to exploit this logic family because of the absense of body effect, drain and source parasitics.

Bulk CMOS process will work OK. Where individual Pwells are available for the Nch devices, the Nch logic path transistors would benefit from being co-located in a Pwell islands each connected to the corresponding CLK or *CLK rotary clock signal associated with the logic gate.

Pmos devices are still required for RTWO top-up function, unless special all-Nmos bridge was used.

To cope with the ‘hot-gate’ voltages seen on gate nodes like GBA, the sampler transistors may have to be higher-voltage devices such as I/O transistors.

Applications—

Logic gates
ALUs
Memory decoders
Synchronous repeaters—buffering using DARL buffers at known-phase points regenerates and retimes data transmissions.
any other digital circuit.
   Advantages
Fastest speed—dynamic logic—all Nch in evaluate path
Two-phase logic—two evaluations per clock cycle.—Differential (true/complement) outputs available.—Fully pipelined.
Clock powered—VDD/VSS connections not required—AC power—very few electromigration problems.—No latches required.
Lowest power—adiabatic i.e. asymptopically zero power—Small area.
No leakage current issues.
Low skew, jitter, phase locking—Rotary Clock, RTWO, ROA advantages
Tiny Data skew—data transistions are forced to align with clock since the data is essentially the same signal as the clock.
forces the clock to be the same speed as the data flow.
   Lightspeed—British Patent Application No. GB0218834.0

The figures referenced below are those shown on sheets 21/53 to 28/53 of the drawings of the present application.

High speed on-chip interconnect using ‘blip’ mode driver and multiphase locked rotary clock for signal generation and sampling timing.

A combination of a ‘blip-mode’ driver circuit, interconnect layout and RTWO sychronisation can achieve very high speed for on-chip data transfer e.g. 10 mm in 70 pS flight time, and is very economic in terms of interconnect, active area and power consumption. Improvements are also possible to multi-phase operation, and rotation locking.

Patent applications International WO 00/44093 and Hierarchical clock GB 0203605.1 are the background material included here by reference.

Note that throughout the text, reference is made to a 4phase system This is by way of an example, and 1phase, 2 phase, 8 phase or any number of phases could be used as the basis of the circuitry. RTWO clock generator is preferable but other clock generators could concievably be applied.

Background.

High speed synchronous signalling over long-distances on chip is difficult in practice due to interconnect parasitics and clock skew/jitter. Possible solutions e.g. use of wide, low loss traces and PLL, differential receivers etc are usually too excessive in chip area or metal usage to be used throughout a chip.

On-chip interconnect operates in either RC mode or LC mode of signal propagation depending on the resistivity of the wire, the rise/fall time of the sending signal [1].

Today, increasingly longer wires, higher operating frequencies and lower resistivity through copper interconnect has led to LC (transmission-line) mode behaviour exhibited on-chip. Ringing and overshoot can occur on incorrectly terminated lines. The usual method of dealing with this involves breaking up long transmission lines into shorter segments (where LC effects are not seen) and inserting repeaters (CMOS inverters) in-series with the line periocially. This drastically lowers the effective propogation speed due to inverter delay and furthermore makes delay variable on inverter characteristics. This latter problem causes data skews and jitter in synchronous busses limiting available frequency operation.

The option of using correctly designed transmission-lines with terminations although viable to 50 GHz [2] is seldom used due to power consumption problems and area constraints [most on-chip network circuits need PLL/DLL and differential receiver, transmitter etc].

This document outlines new circuits and interconnect arrangement which can exploit LC behaviour at low power consumption by using a “blip” driver (meaning a driver with momentary pulse excitement of either +Ve or −Ve polarity) together with pseudo-differential signalling and detection from self-biased inverter receiver.

Circuit/Interconnect Description.

FIG. 1a shows the cross section of proposed interconnect topology on chip configured here to create a multi-bit signal path. Each signal is sandwiched between a power (VDD) and ground (VSS) line to form a coaxial transmission line to transfer an electrical signal from point TX to RX. On CMOS with SiO2 dielectric, the velocity is 0.5 c which equates to 7 pS per mm. Perpendicular routing patterns underneath can be combined at corresponding VDD, VSS points to form a power grid. Signal paths can also change layers and therefore direction. Not limited to orthogonal routing, the layout would work on 45 degree layout rules also.

FIG. 1b is the circuit diagram of a transmitter driver/receiver amplifier/bias. Typical values are.
Transmission-lines
   Length 4 mm
   Metal type: Alumimum/Copper, Thickness 1 micron
   Line width: signal 1 micron, power 2 micron
   Impedance ˜50 ohm
Transistor widths:—all 0.18 u CMOS, gate length=0.18 u
   N1 20 u N2 20 u N3 20 u
   P1 50 u P2 50 u P3 50 u
Resistors
   RFB 400 ohms.

Supply current total 2.2 mA TX, RX when active at 1.5 V supply 4 Gbps

(Compares to Cinterconnect*V*F/2=2 mA−the equivalent current of driving just the capacitance with full-height NRZ signal.)

In operation, a data stream controlled by local clock signals at the transmitter location, pulse either_send1 or send0 signals. A current limited pulse flows through either N1 or P1 down the line at the speed-of-light for the medium (eR=3.9 for SiO2, Vp=root(3.9)*c).

FIG. 2a Gives simulated Spice results for the circuit operating at 4 GHz with drivers driven during one-phase period of a 4phase clock.

Some details to note:
1. Termination impedance is a combination of 1/transconductance of N2,P2+RFB and will be probably be higher than the line impedance. Higher than expected received signals are achieved but reflections are not a problem due to the lossy nature of the line (almost no energy sent at TX will get back—see below).
2. Resistance of the signal conductor may be upto 5× the impedance and so is very lossy and dispersitive.
3. Two modes are operational 1. LC transmission-line mode and 2. slower mode where the effective termination impedance of N2,P2,RFB work with the total capacitance of TXRX line forming a highpass filter.
4. The “blip” of duration can be much less than the total clock cycle time

The highest wiring density is achieved through using the smallest width possible on the signal and screen wires. Using the smallest width possible while still giving transmission-line type high velocities [1] results in sizing the cross-section to exhibit a resistance of approximately 2× to 4× the impedance (Z0) of the line. Ordinarily this kind of attenuation is difficult to cope with because for the usual NRZ encoding, the received amplitude is very data pattern dependent and not easily detected.

Using short-duration ‘blips’ serves two purposes—1. saves power because the driver is only active for a short part of a clock cycle. 2. Fixes problem of attenuation of the lossy interconnect media as it spreads the pulse out in time because the the self-bias receiver's termination effective resistance restores the mid-supply bias in time for the next pulse to come down the wire with RC action.

The key point is that each new pulse is received free of remenants of the last pulse and therefore the receiver can be made sensitive—in this case using a 2-stage amplication involving secondary inverter N3,P3.

Contrast this with any kind of NRZ signal format which on a path suffering this much attenuation would need special precompensation methods to avoid pattern dependent DC drift in the receive amplifier.

[Another option realisable with the same driver circuits is Manchester encoding, but this would suffer a power consumption cost]

VDD and VSS wires are used to shield the signal line, which is centrally located between the VDD, VSS and so exhibits very little magnetic or capacitive signal injection for the expected differential-mode surges on the supply lines.

Additionally, by careful selection of the ratio of the width of power lines vs. the width and spacing to the signal wire can result in cancellation of coupled magnetic noise from one signal line to the next

Finally, the N/P ratio of the N2,P2 reciever circuit is chosen for a self-bias voltage of approximately 0.5×VDD. This eliminates signal amplification of differential swings on the supply voltage at the receiver end.

In total the circuit is very noise immune for following reasons.
Normal differential supply noise does not effect the received signal
Coax construction shields the signal wire
Termination (self-bias) forms a highpass filter with the signal line rejecting lower frequency noise from the supplies and from signal couplings.

VDD, VSS wiring is not wasted and works to supply power around the chip. Interestingly the mutual capacitance they share with the signal line aids in decoupling the power supply.

Importantly, the line can serve as a true bus, not just a point-point data link. Signals can be tapped anywhere along the line—FIG. 2b Plots the signals at various points along the transmission-line. Each tap point can drive a circuit similar to N2,P2,N3,P3 but either (1). without RfB—only the far end needs the self-bias circuitry or (2). using RfB at each detector of higher value to distribute bias along the length. With the high resistance signal wire, mismatches of inverter bias voltage could be tolerated. AC coupling of the intermediate detectors is also practical.

Data at different tap-points will be phase delayed so the best places to tap into the data lines are the points where they cross over the RIWO lines. Here, the best phase (1-of-4 or however many phases exist) can be used to sample and synchronise the data.

FIG. 1c is the equivalent electrical circuit (discounting resistance which is in the wires) illustrating L,C and couplings which exist.

“Blips” are generated using either a monostable circuit triggered from one edge of the local clock, or, by one phase of a 4phase rotary clock sequence [see FIG. 3, FIG. 6 for 4 phase layout of RTWO in grid).

Clocking

It is assumed that the chip with be equiped with RTWO clock structures to give a distributed phase-locked clock available at all points of the chip.

Multiphase clocking (beyond 2) involves making multiple wraps of differential wiring before inserting a net crossover in the signal path to form a single unbroken wire. FIGS. 6 And 7 Show possible 4phase RTWO strucutres arranged on grid basis.

FIG. 5 Shows a set of circuits which can be attached to the 4-conductor transmission line mentioned above at any cross-section point to power and sustain rotation. Conditional inverters CI0 . . . CI3 illustrated eliminate cross-conduction current. Small normal inverters between 180 degree points can be added to initiate start up and together with the CI0 . . . CI3 will work to ensure that only one direction of rotation as determined by the ph0 . . . ph3 sequence desired exists—which has to be matched to the ‘winding’ direction of the RTWO double loop. The alternate sequence of CCW rotation would be poissble either by 1. changing the inputs to CI0 . . . CI3 around or reconnecting the 4phase grid connection points to reverse the rotation direction in the obvious manner.

Signal Serialising

Links can send non-serialised databits at a rate of the RTWO frequency. [as described in the data transfer application, number??? - - - - divisional].

Another option is to serialise data at full rate relative to a lower frequency clock which drives the local logic (as might exist on a 500 MHz asic driven by a /8 counter from a 4 GHZ RTWO. In this case, 8 data bits could be sent per ASIC clock cylce on a single wire).

Clock source.—A 4 phase RTWO oscillator provides the Transmitt clocks.

PhJ,K,L,M are each chosen from one of ph0 . . . 3. PhK and PhL should be 90 degrees apart because when these are ‘AND’ed they set one ¼ of a cycle period for the output ‘blip’ duration.

FIG. 8 is a possible 4 phase layout according to [Hierarchical???? patent number).

Transition Signalling:

Power can be saved using transition signalling—i.e. Only activate either N or P when the data changes. ‘0’ going but would generate the +Ve blip, ‘1’ going event a −Ve blip. Static stream of 0's or 1's from the TX shift register would not cause any signalling event and the receiver retains its last state by hysteresis.

TX circuit of FIG. 3 achives this by comparing the new data bit (Q0) with last databit (Q-1) generating no pulse when data remains the same. [Q-1 is an extra stage on the shift register to store the last data bit transmitted]. The TX register is clocked at the full RTWO clock rate and is loaded in parallel fashion at a clock some divisor of the main clock (via /n counter).

RX circuit needs just a little hysteresis in these cases to maintain the previous switched state in the absense of new pulses at each bit time—Rfb2 can provide this hysteresis.

Forth possible special signal state exists, that is, sending two or more consecutive blips of the same polarity [the transistion signalling will never send this sequence]. It could be used to indicate condition codes e.g. Strobes.if designed to recognise it (This is not shown on any diagrams but would involve modifing the logic at Q0, Q-1 which drives_send1, send0).

Alternative approach could be to signal with unipolar pulses (just N1 firing) but with modified threshold of N3,P3 pair to output a default ‘1’ until an incoming −Ve blip sets Q to 0.

Signal De-Serialise.

The signal lines are routed on chip to the destination point at which there is another RTWO local clock which will be phase locked to the TX RTWO clocks by virtue of hard-wired or other couplings between the rings.—see FIG. 4 and FIG. 7

The choice of phasing is designed to time the data sampling of the RX signal with the exact arrival time of the incoming data pulse +account for receiver amplifier delay. A locally 4-phase RTWO tap gives 90 degree choices. Higher resolution can be gained by ‘sliding’ the sampling point to cooincide exactly with a selected any-phase point. [as described in the data transfer application, number???]

Deserialiser:—

Data from the Q output of N3/P3 is sampled using N4,N5 gated by the overlap of two RTWO clock phases PhX,PhY chosen from two 90-degree separated phases from ph0 . . . 3 (4 phase system). For 2 phase system, one transistor operating off one of the phases would work.

Sampled data is clocked into the local shift register to produce a parallel output every n cycles where n is the divide-ratio of the /n counter.

### REFERENCES

[1] Alena Deutsch, et al, “Modeling and characterization of long on-chip interconnections for high-performance microprocessors” IBM J. RES. DEVELOP. VOL 39, No 5, September 1995 pp 547-567 (p 549)
[2] Bendik Kleveland, Thomas H. Lee, and S. Simon Wong “50-GHz Interconnect Design in Standard Silicon Technology” IEEE MTT-S International Microwave Symposium, Baltimore, Md. Jun. 7-12, 1998 web: http://smirc.stanford.edu/papers/mtts98p-bendik.pdf
   Piped Buffer—British Application No 0225814.3

The figures referenced below are those shown on sheets 29/53 to 31/53 of the drawings of the present application.

High temporal accuracy, high power, multistage pipelined CMOS buffer.

Patent applications PCT/GB00/00175 and GB 0203605.1 are hereby included by reference.

Background

VLSI CMOS logic devices frequently employ buffers (current amplifiers) in order to allow control signals to quickly drive capacitive loads such as those resulting from interconnect or transistor capacitance.

Traditionally, a chain of CMOS Inverters with progressively larger stages will be cascaded to form an effective buffer between a low-drive signal and a highly capacitive load such as a clock load. More stages give a more powerful output and faster transition (rise/fall times) but result in increased propagation delay between an input transition and the output transition. Furthermore, this delay time is not constant but depends on CMOS Process/Temperature and supply Voltage (PVT) variations.

Variations act to modulate the delay time of any buffer and for example a 10% supply voltage variation can produce a 10% delay time variation in the buffer.

In applications such as clock distribution, the temporal accuracy of the signals is vital. For clock system catagorisation, Delay time is termed Skew and delay time variation is termed Jitter.

FIG. 1 shows the usual construction of a standard CMOS multistage inverting buffer.

Until recently, lithographic scaling of CMOS has produced increasingly beneficial performance from buffers. At each generation, the process shrink produces faster transistors which would imply lowered skew but now the transistor variations e.g. length variation on devices with gate lengths of 0.13 u or below can produce buffers with delay times which are badly mismatched with respect to each other even on the same die. Another issue with device scaling is reduced supply voltage and higher supply currents which leads to power supply noise which impacts directly on jitter through delay modulation.

For clocking applications, where buffers are placed all over a chip, and it is critical to match delay times [the exact delay doesn't really matter] buffering becomes problematic and it has been reported that as much as +/−1000 pS uncertainty can result.

Besides delay variations the common buffer exhibits two more undesirable traits.
Excessive input capacitance.
   Each stage has a P and an N transistor with typical total capacitance of 2.5+1=3.5 relative units. For any transition of the buffer all this capacitance must be charged to the other polarity. This slows down the buffer performance because each stage must charge one transistor off and charge the other transistor to turn on before the next stage is active.
Shoot-through, or cross-conduction spikes.
   Each Pch/Nch inverter stage exhibit a direct current path between S-D of the Pch then D-S on the Nch when the input voltage is in transition.
   Upto 10% of clock power is wasted by simultaneous conduction during the transition periods.
      Problem List of CMOS Buffers.

To summarise, the standard CMOS buffer exhibits the following negative attributes:
Excessive delay time of the long inverter chains required (upto 20 distributed stages in clock distribution applications produced by CTS [clock tree synthesis tool]).
Delay variation (skew) due to deep-submicron process control problems.
Jitter introduced by supply voltage noise modulating the already excessive delays.
Excessive power consumption (well above Cload*V\hat{ }2*F) arising from excessive buffer sizing to achieve acceptable delays.

The effects of items 1. and 2. can be largely offset by use of feedback techniques such as PLL (phase-lock-loop) and DLL (delay lock loop), but these will increase the problems 3. and 4. and also impact of chip area.

Pipelined Approach to Buffering of Clock Signal.

To reduce problems 1, 2, 3 above a buffer should be made to have the smallest delay possible: This would suggest the lowest number of stages in a chain, ideally just one stage. However, this is not feasible since the circuit driving the buffer is usually a weak signal—e.g. Logic signal which could not drive the large single buffer directly.

For a periodic clock generation application it is known that the overall delay of the buffer does not matter as long as the delays are matched between buffers and therefore the clock signals are fully synchronous.

This knowledge allows for a pipelined approach to buffering. Pipelining of logic is well known where each logic stage is controlled by a clock signal to complete its logic evaluation before the next clock event whereupon it passes the result to the next pipe stage. Logic pipelines can be long with high overall latency (many cycles) but with a throughput of one operation per clock cycle (once the pipe is full). Creating the simplest form of pipelined buffer is effectively the same as making a logic pipeline but with no actual logic involved at each stage, just passing on the same input state (or inverse of input state) to the next stage synchronous to the clock edge.

**Logic could be added within the pipeline to allow for logical clock gating. If each stage of the buffer pipeline is made progressively larger (in terms of transistor width) the signal becomes stronger (as in it's drive ability) as it moves down the pipeline and can be magnified to any required strength by adding new, increasingly larger piped stages.

Delay time of the pipelined approach is always likely to be greater than a conventional CMOS buffer chain because of the clock overhead but the key point to note is that the delay time is controlled to be N clock cycles (N is length of pipeline)+1 buffer delay time (the final buffer). Uncertainty is that of a single-stage buffer—the N cycle delay time is not relevant to a periodic signal such as a clock.

**Clock gating applied in the pipeline for glitch-free operation.

Separated Path Approach to Buffering of Clock Signal.

The normal CMOS buffer of FIG. 1 has what can be called a ‘combined’ path for the different polarities of signal to be amplified i.e. the circuit path along which a logic “1” input signal travels to the output is the same as the circuit path of a logic ‘0’ through the Pch/Nch pair inverter stages. This leads to excessive delay (mentioned previously) compared to a separated path design described below.

To speed up the delay times of a buffer, it can be split into two paths (two separate circuits combined only at the output and/or input), the “1 drive” and the “0 drive” path.

Each path can be very fast as each circuit has large transistors only to perform the ‘turn-on’ path for the particular output polarity (small transistors are still needed to reset the path ‘off-line’ on the non-active output period but these do not impact the speed). The lack of large devices to be turned-off is in contrast to the conventional CMOS inverter chain where the non-active polarity transistors can slow down the progression of any change of state in the buffer

The separated ‘1’ and ‘0’ paths are combined at the output side and a side benefit to the separated path system is the absence of cross-conduction current spikes when designed correctly. It is straightforward to make the final Nch and Pch devices never simultaneously active by controlling the signal timings of the two paths.

### EXAMPLE EMBODIMENT OF THE IDEAS

FIG. 2 is a block diagram of an illustrative example of a global clocking system incorporating the pipelined, split-path buffer to drive the final clock loads.

A high frequency 4-phase a 3.125 GHz Rotary Clock network covers the whole chip with a phase-locked clock. Local frequency division or more complex waveshaping logic (BWB see GB 0203605.1 application) produces the required clock signals for feeding to the buffers.

In this example, a 1 mm×1 mm grid of BWB and buffers is used and each buffer is required to drive upto 50 pF in its 1 mm2 area.

Moving Spot Generator.

A ‘moving-spot’ pattern generator [FIG. 2] driven from a tap into the high speed 3.125 G rotary clock provides the timing sequence signals for frequency division and/or arbitrary waveform generation. Two stages are shown. For more than 2 stages, alternating stages are clocked with CLK90 and then CLK270 (or other clocks 180 degrees out of phase).

The circuit works by transferring a ‘1’ on the OUTN to OUTR+1 during the ‘high’ time of the respective clock.

This circuit can replace those of [Application GB 0203605.1] and has output waveforms like those in FIG. 3 for a 6 stage design.

The sequence advances on each edge of the 3.125 GHz clock (6.25 GHz rate i.e. 160 pS intervals). Feedback transistors nclr and pclr clear the previous stage back to the quiescent state as the new ‘spot’ position is reached. Bias transistors (not shown) are connected like nclr and pclr transistors but have their gates connected to vdd and 0 v respectively and are sized to provide a light bias current to absorb leakage currents.

Moving-spot generators are located (along with the typically the rotary clock electronics) at the junctions of the Rotary Clock grid. Phasing of the global clock between any two corners is at most +/−30 pS at 3.125 GHz when the correct choice of one-of-4 local phases is tapped. It is possible to design the buffers with slightly different delay times to offset for the known phase difference of the source clocks.

To synchronise multiple ‘moving spot’ generators, the final output of one generator is connected to the input of die next generator on the chip. These links are arranged so that a master generator (which is the only one arranged to produce a circular patern (last output fed back to first input)) is able to force all other generators to move in step with it. It will take many ‘wrap-arounds’ for the synchronisation to ripple around the whole chip.—FIG. 2 shows this.

To minimise the chip area consumed by the moving spot sequencers (which could be upto 100's of bits long) the transistors would be sized close to near-minimum feature size. Such small circuits have weak output drive ability and need to be buffered before they can drive what might amount to a 50 pF local clock load.

Pipelined Buffer Circuits.

A split path pipelined buffer is shown in FIG. 4

The upper path is the “1” output path finishing with a Pch device.

The lower path is the “0” output path finishing with an Nch device.

Each path has some resemblance to the moving-spot generator circuitry in that a signal moves along with each ½ clock cyle, but in these buffer chains the transistor size increases progressively at each stage, perhaps by a factor of 5 each time. For the ‘1’ path, starting with a first stage input Nch width of 8 micron, the final Pch output buffer after 4 stages of 2150 micron enough to drive 50 pF in under 200 pS.

The input to the first stage of each path is routed through to one (or more using ‘OR’ gating) of the outputs of the moving-spot sequencer.

In the example simulation, input to the ‘1’ path could comes from Q0 output of the moving spot generator, which the input to the ‘0’ buffer path could come from Q4 of the moving spot generator (which is two full cycles later of the 3.125 GHz clock).

The results of this arrangement are graphed in the Spice results of FIG. 5a and FIG. 5b

Pipeline delays from IN and IN_N—rename to Q0 and Q4 are not important for the generation of a cycling clock signal.

High-frequency clock power consumption to drive this pipeline is low when a Rotary Clock tap is used since the capacitive energy is recycled.

Shoot-through current elimination: Shown on the “1” path of diagram FIG. 4 are transistors which reset the gate on the final Pch (w=2143 u) transistor. This circuity is driven by an ‘early’ output ‘out_lastbut1’ from the ‘0’ path chain. An active signal here gives an early indication that the ‘0’ output transistor is going to be switched permitting the large Pch to be switched off in time to avoid shout-through conduction currents in the output stage. Circuity to turn off the ‘0’ output transistor by an early indication from the ‘1’ pipeline is not shown but can easily be derived from the previous example.

With logic gating and programmable tap-points from the moving spot sequencer to the two buffer paths, an arbitrary waveform can be created with resolution of 160 pS.

Choosing the other two phases of the 4phase clock can offset the sequence by +/−50 pS.

Because the moving spot sequence is cyclic (wraps around), a continuous waveform will be generated at the OUT port with reduced frequency than the global clock rate.

[Note, the time scales of FIG. 4 and FIG. 5 are not aligned]

Since all the moving-spot generators on chip will be operating in synch, arbitrary local clocks can be created but which have precise phase and frequency relationships to the other clocks on the chip. This helps with SOC integration of multiple IP blocks.

There are other options besides use of the arbitrary waveform generators (moving spots +programable decode) to provide the IN and the IN_N signals for the split pipeline buffers. One idea is to use globally distributed IN and IN_N signals coming from external pins. The distributed IN and IN_N signals can themselves be pipelined (i.e. Re-sampled and re-launched periodically on the higher-frequency rotary clock clock edges within the distribution) to maintain alignment. Using this arrangement allows external control of the internal clock buffers from, for example, external test clock generator. There would be latency in terms of N cycles but the random variation is still small—that of the last few buffer stages.

### OTHER REFERENCES

[Lui] Retiming and Clock Scheduling for Digital Circuit Optimization, IEEE transactions on Computer Design and Integrated Circuits and Systems Vol. 21, No. 2, February 2002 [Lui] Xun Liu, Marios C. Papaefthymiou, Eby. G. Friedman.
[TIM] M. C. Papaefthymiou and K. H. Randall “TIM: A timing package for two-phase, level clocked circuity” Proc. 30^{th} ACM/IEEE Design Automation Conf. June 1993.
[Timberwolf] C. Sechen and K.-W. Lee. An improved simulated annealing algorithm for row-based placement. In Digest of Papers, International Conference on Computer-Aided Design, pages 478 481, Santa Clara, Calif., November 1987.

Figures and diagrams reference to in the specification hereinafter are those shown on sheets 32/53 to 53/53 of the drawings of the present application.

To design synchronous i.e. Clocked VLSI devices require a combination of circuit and software techniques and/or algorithms.

This invention relates to a series devices which may act alone or together to aid in the achievement of low-power high frequency Global VLSI clocking (meaning across the whole chip as well as local clocking) and support circuitry and software to complete an industrial design capable of supporting run, test and diagnostic modes. Specifically;
Global high frequency synchronisation through Rotary Clock network.
Globally distributed synchronisation of low-speed (multi-cycle) events.
   Moving-spot synchronisers sub-sampling lower rate events and acting over the whole chip instantaneously [drawings sent to Keith]
Global low-latency high speed data interconnect mechanism (synchronous OR asynchronous [latter is the circuit shown to Reshape])—GB 0218834.0
Programable frequency division and/or programable phase offset to support legacy sub-GHz clocks.
Low skew/jitter buffing mechanisms for clock signals—0225814.3 (Jun. 12, 2002)
Adiabatic frequency division components—GB0203605.1 (15/2/02)
   AND idea shown under NDA to Conrad Umich.
Adiabatic, energy conserving Logic family—GB0214850.0. (2716/02)
Energy conserving high performance latch techniques as discussed hereinafter
   incorporating ‘gating’ [Re previous patent]
      General Trends in VLSI Design

Here we talk about trends seen in the last 5 years which impact how VLSI chips are designed and implemented.

Interconnect

The biggest change has been from the previous ‘transistor-dominated’ design methodologies to moden ‘interconnect dominated’ design. Historically, when Tansistor and therefore logic gate delays dominated the design of synchronous systems, little regard was paid to interconnect delays.

Today interconnect delays dominate circuit performance. Clocking is one instance of a long-reach signal—others issues apply to all interconnects exceeding perhaps 0.1 mm in length when the interconnect delay time can exceed that of a logic gate.

Interconnect must be treated as a first-class physical effect and not as simply as ‘parasitic’ with associated margins to account for the effect.

Timing Problems.

Since interconnect delays are becoming dominant and often it is hard to predict the delays until a circuit layout is complete, ‘Timing analysis’ and ‘Timing convergence’ have become essential—Delays must be based on actual placements of wires, buffers clocks to make sure the synchronous system will work (all Setup and Hold times on all paths must be met).

Changes to layout may be required to meet timing constraints and this situation can frequently result in ‘Timing Convergence’ problems where a new layout is tried but which leads to new timing violations elsewhere in the design leading to iterations and delay to market.

Concept of a Clock

In a synchronous system, data is controlled by the operation of a clock signal. The clock controls the time at which data is allowed to change (output clocks) and also the time at which data is captured (input clocks).

The clock is a global signal routed to all latches on the chip. It therefore has the most ‘parastic’ interconnect effects of any interconnect and so is subject to the most scrutiny. In fact it must be remembered that is is the relative timings between clock and data which is important (something that is often overlooked).

Concept of Register (Latch or DFF)

A register here referrs to either a pass-latch (also known as level-triggered flip flop). Or edge-triggered flip flop (e.g. DFF). Either of these devices is able to control the progression of a data signal from input to output by use of a ‘clock’ input signal. The terms Register, Latch or DFF are used interchangably in many papers and the exact meaning must be inferred from the context.

Concept of Cell

Cells are the generic term for a pre-designed layout pattern which when instantiated somewhere on a chip yields a functional component (e.g. NAND gate, multiplexer, latch) after manufacture. Cells are hierarchical—bigger cells can contain smaller cells wired together. The lowest level cells contain transistor layouts. Most higher level cells just contain sub-cells and wiring.

Concept of Paths

For synchronous systems, the concept of a ‘Path’ extends the idea of a netlist to encompass groups of signals originating from registered outputs, which combine logically (logic gates) to ultimately arrive as a single bit input to a single register. with some complex time delay characteristics.

The path concept fits well with the realisation that most logic operations are reductions, usually Multiple inputs->one output.

Constraints on timing relate to paths because:
1. Relative timings between clocks and data changes are important.
2. Any one of the inputs on the path can possibly change the ouput which feeds the latch.
   [path_and_parasitics.ps ????]

A single Net can be involved in mulitple paths—several registers may have their inputs determined in some way by data on one Net.

[Note that the simple Nets assumed during design may be replaced by complex interconnect parasitic networks which exhibit delay]

To find all the components of a path involves a search of the connectivity database (the netlist) starting at the D input of a DFF of a register working ‘backwards’. Doing this search will typically be done using a Graph-database package. The search result ‘fans-out’ as the algorithm progresses collecting Nets and Cells involved in the path until ultimately every branch had ended in the output of another register.

Path analysis is primarily used for timing analysis and is not usually concerned about the logical functionality (except where false-path analysis is determined).

Registered elements produce and receive signals at fairly well-defined times (given by the clock) unlike logic-gate paths and interconnect whose speed can vary greatly. The primary purpose of clocks+registers is to remove timing uncertainty by adding delay or storage.

A Path for the purposes of this paper is therefore is the collection of time-delaying items (interconnect and gates) between the (clock-stablised) registered outputs and a registered inputs.

Static timing analysis is used to check that none of the paths in a circuit fail because of setup or hold time violtation.

Setup and Hold Constraints

The typical DFF register (from the user's point of view) responds to a rising edge of a clock waveform—capturing the data signal value which existed before the edge of the clock. In practice the DFF is not an instantaneous device.

Well known constraints on synchronous systems are Setup and Hold. The diagram shows to possible problems when sampling data. In both cases above, a ‘0’ is intended to be captured since the data is zero before the rising clock edge occurs.
Hold time violation: Data must be held stable for a small time (Hold time) after the rising edge or else a Hold-time violation occurs.—In the diagram above the first clock pulse is supposed to clock in a ‘0’. But, the data changes from ‘0’ to ‘1’ too soon after the rising edge which might cause the ‘1’ to be sampled instead of the ‘0’. To prevent hold time problems the data must not change until at least the DFF's specified hold time after the edge.
   Fixes: There are three possible fixes to hold-time problems.
      1. Make the logic circuits in the data path slower—so data cannot change too soon
      2. Adjust the clock phase to the register so that it occurs earlier.
      3. Adjust the clock phase of all the registers which feed this path to a later phase (achieves the same as (1) above but constraints apply.)
Setup time violation: Data must be stable for a sufficient time (Setup time) before the clock edge occurs. Above, the second clock pulse is expected also to sample ‘0’. But, there has not been enough setup time prior to the rising edge and so a ‘1’ (the previous state of the input) might be sampled. [This occurs because a DFF is NOT really an edge triggered device it continuously samples the input state while the clock line is low. This sampler cannot respond instantly to changes in Data.].
   Fixes: To fix setup time violations there are three choices
      1. Make the logic circuits faster so the data changes in time for the clock.
      2. Adjust the clock phase of the register to occur later
      3. Adjust the clokc phase of all the registers which feed this path to an earlier phase. (achieves similar to 1 above but subject to constraints)

From above, the symetry of the Setup and Hold problems can be seen in respect to the cause and possible solutions. Known methods of moving clock phases are called variously ‘Scheduled Skew’, ‘Slack-Borrowing’, ‘Time stealing’ and is accepted industry practice.

Another method of sequential circuit optimisation is called ‘Retiming’ [Ref SIS paper] where the positions of registers are moved along the paths in an attempt to equalise the delay times. A register feeding the imput of a logic gate can be moved to the output of a logic gate (or vice versa) depending on well known rules which maintain logical equivalence and timing

Hierarchical Clocking System (the Priority Document Hierclock)

Earlier rotary-clock centred circuits focusing on improving clock generation and distribution [previous figures in hierclock application] by forming grids of rotary clock structures were given. 4 phase distribution was outlined as an option. Localised clock division and arbitrary waveform generation for multiple frequency/phase related clock generators over the surface of a chip was discussed and called BWB (Binary waveshaping blocks). Key ideas were the global synchronisation of events using locally communicating state machines arranged in a chain to avoid the long-distance communication overheads.

As these ideas have been refined, a proposed test chip architecture is possible as shown in [testchip4.ps ???]

Other recent developments and improvements to the hierarchical clocking scheme are set out in the rest of this document with appropriate background information . . . .

Slack Budgets & Multi-Phase Clocking—the Concept of ‘Slack’, ‘Critical Path’

Slack is just a measure of the amount of ‘spare’ or ‘slack’ time available on a synchronous path before a Setup time violation might occur. If all paths of a synchronous machine exhibit slack then the clock cycle can be reduced until one path becomes ‘critical’ i.e. it reaches the setup-time limit. Ibis is then the Critical-Path of the system and sets the time (in single-phase systems).

Multi-phase synchronous systems (as well as so-called asynchronous system) i.e. Those which can have more than a single timing reference are able to break this time limit by resheduling the pipelines to pass slack from fast-paths onto slow paths which suffer tight or negative slack. The limit in these cases is that for a pipeline of N stages, the sum of all the delays of N paths along the pipeline must be less than N*tcyle. For example a 3 stage pipeline operating at 1 GHZ could have paths of 0.5 nS, 2 nS, 0.5 ns and it would still work at 1 GHz

Slack is measured in units of time, typically picoseconds and must be zero or higher under all conditons for a synchronous circuit to work. Negative slack numbers sometimes appear in timing analysis meaning thet the clock period must be increased for the circuit to work.

Slack, which refers only to setup-time constraints, is the term most widely used in the literature to describe timing issues. Hold time violations for the typical DFF edge-triggered, single-phase systems are easily fixed and often do not receive much attention. For general analysis, it is not possible to study a synchronous system purely in terms of slack especilly where multiphase clocking or transparent (level triggered) flip flops are used.

The complete conditions for synchronous operation given Setup and Hold constraints are given in [Lui].

Traditional Synchronous System Design Flow

Design of a synchronous machine involves CAD tool steps to produce the photolithographic outputs.
5. High-level-descripiton (HDL) e.g. VHDL, Verilog source code created by a human designer.
6. Logic synthesis—mapping the intended logic and state transitions to a combination of pre-designed Latches, Gates and Buffers (collectively known as cells) and Netlists (interconnects) to implement the function. Clocks control the latches and control the state change from one to the next and are often assumed to be single phase control lines routed all over the chip.
   The timing of the circuit is only an estimate at this point because until the chip is placed-and-routed the final parasitic capacitances are unknown and can change the critical path length.
7. Place & Route
   Place: cells are positioned on the chip layout using a CAD tool which often attempts many possible layout configurations to optimise various functions such as ‘minimum wirelength’ ‘optimum timing’.
   Route: Auto-routing software takes the placement information of the cells determined by above, plus the Pins (inconnect locations on each cell) plus the netlist (which pins connect to which other pins) to determine the interconnect paths.
   Placement is normally not affected by the idea of clock signals because it is assumed the clock line will be available everywhere like the power lines.
   Routing of the clock lines is performed by a special tool called ‘CTS’ Clock-Tree-Synthesis, a special auto-router e.g. H-tree which can also insert active buffer elements on the more advanced versions.
8. Timing analysis and Convergence.

Today in industry there are many possible approaches to the above tasks. Most algorithms mentioned above use heuristics and iterative approaches to optimisation. For example, a well known Auto-placement code called TimberWolf uses a ‘Simulated annealing’ method. Cells are moved at random and each new placement is evaluated to see if it improves the goal (lowers the cost-function) of any number of factors which are evaluated at each iteration. Common cost functions are total wiring-length, delay time. Clock related placement of latches is not undertaken since a ‘single-phase-everywhere’ methodology means that the clock is seen as a global resource much like power and ground.

Mutligig Rotary-Clock Design Flow

1. HDL
   Identical to above
2. Logic Synthesis.
   Identical to above. A standard tool runs from the HDL code to produce a list of logic gates, an initial list of registers and a netlist giving the interconnect between items.
3. Sequential Optimisation and phase-spreading methodology.
   This is a new step but based on known ideas.
   The following operations are performed on the netlist in accordance to the specified reference papers.
      a) Retiming
      b) Clock skew scheduling
      c) Optionally conversion from edge-triggered to level-triggered flip-flops [TIM paper]
      are performed sequentially or simultaneously [Liu]
   The result of a, b, c above is a new netlist where the logic gates remain the same as a standard flow but the registers configuration is changed (we do not discount the possibility of doing logical optimisation such as Espresso [berkeley] tool at this point). The number, placement (in the netlist) for each register may be different to the standard flow. Addionally a clock skew schedule (annotation of the optimum phase of each register) is produced and it is a methodology for mapping this schedule (via placement) onto the Rotary Clocks' natural ability to generate multiphase clocks which is one aspect of the invention outlined here.
4. Place and Route.
   We call this type of algorithm, where logic path cells are placed relative to latches which in turn are placed at known phase-points of the clock, Placement Driven Timing’ to contrast with the usual ‘timing driven placement’ which attempts to place based only on data timings, assuming usually a single-phase clock or at least a clock with small amount of skew.

The prototype of the improved flow uses a new cost functions built into Timberwolf to promote the placement gates close to the appropriate latch. On each placement iteration of the simulated annealing method, the tolerance of phase is detemined for each unconnected output of cells which are to feed the D input of a latch. If the placement is close enough to a latch, which by connection to the local rotary clock phase, has a suitable phasing, the placement is retained. The final drawing of designflow.sdd shows that any one of 4 possible phasings is available for any latch just by permutations of the via pattern into the Clock lines. Therefore 4 possible phrases can be evaluated fur every possible latch greatly increasing the chances that a suitable timing can be found and a complete spread of loadings onto the Rotary clock will be achieved. Use of transparent pass-latches will extend the margin even further.

Results of the placement feed to the Routing phase of layout which can be achieved with standard tools.

The flow is outlined as a flow chart in the diagram
(timberwolfflow.sda ???] and in more
detail in (designflow.sdd ??]
   Testing of Rotary Clocked Circuits.

Coupled LC based oscillators like Rotary Clocking [ref original patent] are inherently difficult to stop for gating, testing purposes because energy is contained in the circuits and cannot be immediately released in a fully controlled way.

The rest of this section describes in-principle additions to latches and ancilliary circuity to allow for single-stepping, BIST and scan-testing to be performed on Rotary Clocked chips through indirect means of modification of the storage elements (latches or DFFs) which are driven by the clock.

The basic principle is to synchronously data-gate latches connected to the clock lines to mimic traditional clock gating where, say an AND gate is inserted in the clock path. There is a direct equivalence of clock gating and data-gating and no perceptible difference externally and no difference in area to implement.

Synchronous Data Gating (as implemented within the proposed latches further below Previously suggested circuits
Patent [PCT, current one ????] has descriptions of data gating for Rotary Clock as an alternative to clock gating.
   This is EXACTLY equivant in terms of effectiveness BUT can save area because stopping activity upstream will, within a few cycles stop downstream activity. [new concept of looking through the BDD? graph and finding where are the best places of data gating to stop forward switching activity—might only be a few such places]
Patent [PCT, earlier one perhaps] has
   power-down of rotary clock—this can be done OK once an orderly ‘stop’ had been performed using the latches.
   descriptions of real-clock gating with pass transistors
      Newer Circuits:

Propose here methods to extend the above concepts and synchronously gate latch elements driven by a rotary clock to prevent spurious sampling.

These circuits require circuitry [Keiths new circuits] for multi-cycle global synchronisation using locally cooperating state machines operating of a phase-locked global clock.

Latch Technology to Suit Rotary Clock Flow

All synchronous system rely on some kind of latching element to control data flow. These are referred to variously as Latch, D-flip flop (DFF), Register. These circuits use clocks to make path delays less uncertain by allowing changes only a specified times relative to the clock timing source.

Since the late 1980's a single-phase edge-triggered D flip-flop methodology has been preferred industry practice. The biggest barrier to the previously common multiphase clock distribution methods has been the difficulty in creating and distributing more than one clock phase while maintaining relative phase accuracy one other.

For Rotary Clocking, many different DFF, Pass-latches designs were evaluated. However most latches and FFs use internel buffers and inverters because of their single-phase lineage. When driving from a true differential clock source such as Rotary clock these are not required.

Another useful attribute for any latch device used with an L-C based clocking scheme is constant capacitive loading presented to the Rotor wiring (clock loading which doesnt depend on the data being passed through the latch). Without this there can be pathelogical worse cases where all latch data switches from 0 to 1 changing the capacitance, therefore period, and therefore phase stability.

There is a lot of inherent tolerance to capacitance variations afforded by the multiple rings of a rotary clock.

True DFF Latch

Fig? Shows a true edge-triggered DFF latch suitable for use with Rotary clock. It has many of the preferred features regarding clock inputs listed previously for Rotary Clocked operation.

Note:
that the feedback from the buffered output and the STOP components gives an edge-triggered characteristic where the output state cannot change after the active rising edge no matter what happens on the D input
PS and NS are turned off at the inactive part of the clock cycle to re-arm the latch
   [dff_fast.ps]
   (picture of waveforms from above)
   Pseudo DFF Latch Proposal
   [constant_clock_C2.ps—with the SRAM I/F]
   (picture of waveforms from above)

A design of a simpler and faster latch element is shown in Fig?.

This circuit is essentially a pass-latch but is intended to be characterised and operated like a DFF.

Since it is transparent while the clock is high, it exhibits a long hold-time characteristic compared to a DFF for which it is a stand-in. However it transpires that at very high frequencies this hold time is less than ½ of a clock cycle due to delay times in the output stage of the latch and there is very little difference between it and a master-slave latch when operated at one specific, or a small range of operating frequencies—perhaps 2:1 range.

Safe useage of this latch for multiphase clocking requires that the sequential optimisation stage meets setup/hold times of all latches.

The latch is designed as a split-path where the Zero and the One circuits are separated to improve speed and to eliminate cross-conduction.

Note:
Clocked transistors N1,P1 are not inline with the data but connect to the supplies. Gate capacitance is largely unvarying with data input value since the channel of the clocked transistors fully charges and discharges from a solid path, to either VDD of Gnd at each half of clock phase for both clocks (true and complement) through the transistor source connections.

Hold i.e. Stop arrangements:

Transistors N5, P5 control the “effective clock-gating”. While for SOI processes, true clock gating is feasible with Rotary Clock, bulk CMOS has too much RC to perform clock gating efficiently. It was shown in [PCT????] application that there is seldom any need to gate the Rotary Clock (why disable the clock when it isnt using much power?) but for SCAN testing (see section further below) it is essential to hold the state. N5, P5 perform ‘data gating’ which is ‘effectively clock gating’ to hold the state of the latch when *STOP is high and STOP is low. Also, choking the data makes downstream logic of the latch inactive reducing data-activity related power consumption—again directly comparable with clock gating.

(Ideally the stop signals have a low-impedence turn on/off drive characteristic but a high impedance quiescent drive to to isolate the gate capacitance from the D input path as far as it would slow down the operation of the latch.)

Generation of the STOP signal event must be carefully controlled in time. The global synchronisation method outlined in GB0203605.1 and improved versions of this circuit outlined here can achieve this globally simultaneous “STOP” signal which immediately freezes the state of the whole synchronous machine—at which point the state can be dumped.

Effective “Functional clock gating” can be implemented where the STOP signals are generated from logic signals—possibly qualified by the local rotary clock to ensure Start/Stop occurs only during latch inactive time.

Clock activity will usually continue during the Stop period so that restart can be synchronous and glitch fee.

Using Pseudo-DFFs with Different Clock Phases

The latch discussed above could, if neded, be used in pairs to act on one signal. Each latch of the pair having different *CLK and CLK orientations to implement a non-shoot-through DFF type arrangement which would work down to very low speed.

A further option is that the pair could use 90 degree (4 phase) relative alignment and given the delay time would not suffer shoot-through over a broad set of high clock frequencies.
This represents a very aggressive methodology but supply voltage binning ought to push all the hold-failures away—if chip is failing on hold times, reduce supply voltage. Will move the potential over to setup time failure—but with transparent latches will be some budget here also.
   Global Synchronisation Methods—e.g. Generating the STOP Signal for Latches Over the Whole Chip at the Same Time

It is well known that it is difficult to transmit a global signal across a chip within a very short clock cycle. Measures such as true transmission-line techniques (lightspeed application) can extend the distance a signal can move in a given time period but often the overhead of such an approach is not needed when update rates are slow.

The goal of the circuits given here is to make a generic low overhead method of synchronisation of low-speed external events with high-speed internal Rotary clocking. The signals are ‘undersampled’ in that many Rotary clock periods are allowed for a low-speed signal to become stable (giving them time to propogate fully across the chip from external pins) but after this /N count latency of the high-speed clocks, the event can be simultaneous over the entire chip.

One such use of a signal would be the STOP signal for latch control (see Fig? Latch design). For example, an external STOP signal is driven onto the chip and the resynchronisation method (operating off the locally inactive phase of the clock) will generate the required STOP signal without corruption.

With the ability to effectively stop the whole chip simultaneously over the entire chip area, the usual problems of slow interconnect are overcome at the expense of latency.

The necessary mechanism for global multi-cycle synchronisation through multiple short-distance local synchronisation links was decribed in the [original hierarchical clock filing] in the section on Multiple Global, frequency-divided clocks.
additional diagrams [keith drawings] are offered here as illustative further examples of the details of how this could be implement.
(Keith's version of the divider—circuit he sent to me).
   Modified Gates—Incorporating Latching Function.

[nandlatch.ps ???] The only changes relative to a standard NAND gate are the clock gated power transistors. When clock is inactive, the gate is not powered and is unable to drive the interconnect. In the active portion of the clock, the output capacitance is charged with the normal nand function !(A&B). Gating in this way can control the output transistion time for early input signals.

Gated Interconnect (i.e. Synchronous Repeaters)

[gated interconnect.ps ???].

Gating of data can be perfomed outside of logic gates and latches. The drawing [fig?] shows gates placed in-line with the interconnect. There will be some data-dependent clock capacitance and this can be tolerated to a limited amount. When buffered it becomes a synchronous repeater. These items and the modified gates of [fig???] would typically not be inserted to hold state (so do not need to be ‘Stopable’) and function to equalise the delays around multiple branches of a path [depends on sequential optimisation strategy].

Testing of Digital Circuits (Background Information)

Synchronous VLSI chips require the clocking system to provide not only system timing to control latches and other storage elements but a mechanism to aid in testing of the finished silicon which can exhibit several forms of failure usually from physical defects caused by e.g. Contamination or optical problems during manufacture/lithography respectively. Some of the most common faults are:
1. Suck-At fault
   this is where a defect causes a circuit node to be stuck at logic ‘0’ or logic ‘1’.
2. Delay fault
   a fault which doesnt affect the logic operation but causes a path to take a (usually) longer time to evaluate than normal. This faults prevent the device working at the intended clock speed and can reder the device unsalable.
3. Leakage current fault
   where dynamic nodes can fail to maintain its charge for the mimimal amount of time. This fault will show up by a device not working at all, or else failing at elevated temperature or lower than nominal operating speed.

The above are usually random failures in manufacturing and reduce yield somewhat, but even a device designed correctly is subject to other systematic faults which may affect every chip fabricated—sometimes optical interactions or combinations of manufacturing tolerances can create unintended features on chip at the same point on every chip, or at the same regions of the wafer.

Systematic faults are the most troublesome and must be debugged and can require a re-spin of the masks, or rework to the process. In either case, unless diagnosis of the problem is possible through testing, then correction is impossible and the yield could be zero.

External Test/Debug

Debugging from outside a chip is of limited use these days—only a tiny fraction of the signals which a VLSI device uses are available on the external pins for measurement. The same problem applies to stimulus—not enough pins. Finally the speed at which modern chips can run is often 10× or more faster than a production-line tester can operate at.

Testing Aids (Internal).

The current solution is to devote on-chip hardware specifially to enable testing of the device itself using test patterns. These digital test patterns can excersice the internal logic of a device with known stimulus, and since the logic is supposed to be deterministic, the output should be predictable if the device is functional and this output can be tested for compliance to check if the chip is working.

For conventional JTAG (a published standard) scan testing, the test patterns are generated using ATPG (Automatic-Test-Pattern-Generation) software during the design of the logic elements through logic synthesis [ref: SIS public domain system from Berkeley]. The test patterns are designed to fully exercise the logic to reveal any possible stuck-at fault. Using shift-registers (or possibly the DFFs reconfigured to act as a chain) to shift in the Test-pattern as a machine state (a synchonous system is defined at any time entirely by the states inside its storage elements) a single clock pulse can be issued to move the machine state onto the next state. Then, the new state captured from the logic is read out and compared to the expected result.

This is a time consuming process and tester-time is expensive. Another drawback is that scan-based approach traditionally can only identify stuck-at faults, but not delay faults of leakage faults since the clock period generated by a tester is generally not fast enough. A second approach is called Biult-in-self-test (BIST) where on-chip pseudo-random pattern generators are employed. Each of these generates a deterministic but highly changeable pattern (squenced by the clock) and the pattern feeds the logic. Outputs from the logic are captured and condesed using a type of running checksum algorithm, again synchronous with the clock. After a long series of many clock cycles the checksum should be of a known value if the logic is functioning correctly. This can be tested against a known-good sample checksum or a checksum computed by software which is aware of the generators' pattern and the checksum generator operation.

BIST has the advantage that it will work at full clock rate unconstrained by a tester's limitation and also that it is very much faster to self-test.

Problems are that fault-coverage is not 100% and debugging at a detail level is more difficult since it is not feasible to preset the exact state of the chip.

Coverage of delay-faults is incomplete as many times delay faults are due to coupling issues not always captured by the pseudo-random sequence.

Scan-Type Circuits

Here is an example of the scan methodology applied onto a Rotary Clocked circuit and makes use of ‘Lightspeed’ links to transmitt serial data, such as scan data, faster than oridinary repeated-interconnect.

[scanlatch_PCT.ps]

Features of the circuit shown above
Single-Step able (using the external step signal)—probably one internal pulse in 100 clocks
   Run at full speed upto count N then stop and dump the state (difficult but fast method of finding the faulting cycle)
   Scan in a complete state (moving spots doing the sequencing at high speed)
   Scan out state at high speed using lightspeed link
      Timing Sequence
Scan in with EN_m and EN_s inactive.
   Q will hold previous value
      (Scan out—M will be sampled (old state read out) in one ½ cycle)
   M will be set by scan in on the next ½ cycle from moving spot register
Step-and-Stop
   Synchronously all over the chip, CLK goes LOW (Oust prior to the single-step cycle)
   EN_s should go high now while CLK=LOW (ready for high time) which doesnt cause any output
   CLK goes HIGH, Q (slave) output begins to go valid from the data in the master (last scanned in, or last sampled from D)
   EN_m goes high during CLK=HIGH time (*CLK inactive) which allows the master to sample when the CLK will go back low
   CLK goes LOW again (*CLK goes high) Master is sampling the data,
   EN_s should go low to prevent the captured data going forward on the next ½ cycle.
   CLK goes HIGH again. Master stops sampling the data,
   EN_m should go low to so next time clock goes low, a new sample isnt taken (or else it will spoil the delay-fault test because there would be a whole new time to sample)
      (Unrelated Possibility here of doing a virtual /n on clock e.g. sampling multiple times without Qs changing)
Scan out/in
   Scan out and in can be performed now—e.g. input new vectors while getting out the old ones.
   compare off-line the readout compared to the predicted ATPG vectors -OR- new step.
      Now the Goto step again (based on universal chipwide event)

The above will find delay-faults because if new data is loaded in, it gets Output fresh in a new period.
EN_m can change when CLK is high (*CLK is low)
EN_s can change when CLK is low
   SRAM Type Interface to the Latch Data
   [fig???.ps]

Typically a scan-chain technique would be used to scan-in and scan-out test data to a chip (sec above).

An alternative circuit proposed here uses an SRAM-type interface to the latches giving random Read-Write access.

According to the prefabricated Rotary Clock layout technique outlined previously, latches can be arranged as Rows and Columns underneath the clock lines (latches can also be placed anywhere and wires can connect them to the nearest rotary clock lines). This Row/Col layout corresponds exactly to an SRAM layout (well known in industry) and with modifications the Latch storage element can be configured to work exactly like a The latch shown has transistors N7 . . . N9, a single Column select line and Row select lines WRITE, READ. Data signals are also routed in metal layers different from the clock structures in a simular X/Y pattern. Row, Column, Data signals would be routed to Pads to get the signals off-chip to connect to a tester. Additionally the chip itself (perhaps an on-chip test controller) could drive the SRAM interface to the self-test latches.

The SRAM overhead is very small—a 10×10 mm chip with 100K latches represents a 0.1 Mbit SRAM—tiny by modern standards. The same chip is likely to have 2 Mbits of cache memory on-board. The overhead on wires and pins is small. The test-mode does not have to be sub-nanosecond access (unlike cache) so design is fairly straightforward. Internal control of the STOP signal and SRAM Read/Write interfaces permits arbitrary localised testing, state dumping/restoration of the latch state (perhaps to external memory) and can help facilitate power-down modes.

Random access testing solves two problems typical of Scan chain methods:
1. Excessive power from scan-chain activity (usually causes excessive power consumption because all logic items on a chip will be activated by the shifted data) is eliminated.
2. Testing bandwidth is improved relative to scan-chain because the SRAM testing interface is inherently parallel (low-speed parallel testers can achieve higher throughput).
   N-Count Test Mode:

Whether Scan or SRAM interface, taking a snaphot of and then dumping the state of machine enables very powerful diagnostics.

One such scheme practiced in Industry is binary-search testing.

In this mode, the state of the machine (state of all storage elements) is initialised (either Reset or Preset with scan-in vectors). Then, N-clock cycles are issues which moves the machine onto the Nth cycle.

The state is dumped externally and compated to the state predicted by a simulator which is emulating the hardware. If the two sets of state data do not match then a logical operation has gone failed somewhere in the N cycles. The test is repeated from the same initial state but with N/2 cycles and the state compared to the N/2 states predicted by the simulator. The next test might be N/4 or N*¾ depending on the results of each compare. Very quickly the exact clock cycle which caused the fault is determined.

The drawings [testchip4.ps???] shows an external counter used to drive an on-chip STOP signal after N counts using the global synchronisation of lower-rate events detailed previously in this text.

The ‘STOP’ signal is given to the chip after counting N events.

Obviously the /N counter could also be internal on a production chip.

The global synchronisation circuitry [global_synch_system.ps ???] method could be employed—One of the control inputs shown could be the ‘STOP’ signal for which the circuitry shown could transfer this over the chip. For the N-cycle-then-stop signal input, latency can be used in the same way. There may be Y cyles of latency on-chip in the N-cycle-then-Stop scheme (say 8 cycles delay) for the STOP but if the tester enters N-Y instead of N as the number to the register shown on [global_synch_system.ps ???] stoppage will occur on the correct cycle.

Power Saving Modes.

Previous Hierarchical clocking scheme outlined methods of frequency control. Previous applications showed voltage regulation and power-supply voltage changes to reduce power when Idling.

This can be extended to:
Voltage scaling simultanous with Speed changes. E.g. Gradually dropping frequency (smoothly) while lowering supply voltage—this could easily be achieved here. Also, if data is gated, chip voltage can be reduced to below that which it would be logically functional but state is not lost.
   Software Flow Improvements

A common requirement when applying Rotary Clock methodology to an existing design would be to improve performance and reduce power consumption.

The existing design is most likely to be a Single-phase, assumed zero (or low) skew methodology using DFF registers.

A well known method of improving synchronous performance is to apply pipelining. Pipelining inserts storage elements between sequentially placed logic gates in a path to reduce the number of gate delays before resynchronisation.

Definition of ‘System Register’, ‘Pipeline Register’

A system register we define as one of those coming from the original DFF synthesised circuit (before being fed into the special flow). Extra registers added to implement pipelining for the Rotary Clock flow are defined as ‘pipeline registers’.

Keeping the ‘system registers’ at the nominal ‘same-phase’ tap points on the ring means that the high-level timing analysis doesnt change.

Design/timing analysis using pseudo-DFF style
Design for the data changing before the clock edge (like a DFF)
   Benefit Transparency gives some safety factor, that if an edge arrives late it will propogate through late and hope that this lateness will not accumulate downstream such that things fail.
   Can use standard timing analysis
‘System’ registers (not the pipeline registers) can be on the single-phase portion of the ring, say +/−2.5%=5%=10% of the loopa and might simplify timing analysis.
   System registers can be used as ‘reference’ point in the timing analysis engine rather than worring about all the delays to help reduce explosion of possible state/time transition graph.
   System registers probably correspond to the low-speed ASIC registers before Rotary-Clock pipeline elements are added (pass latches) and represent a good sign-off point of the architectural.
      Choice of Synchronising Elements During Sequential Optimisation

In the flow to be outlined, the algorithm which undertakes retiming and clock sheduling and will choose the appropriate device from the list above. A full DFF (or two pass-type latches back-back on opposite relative phasings) would be chosen for system registers (as defined above), a single Pseudo-DFF would be chosen when the hold time requirment of the pass-type latch does not cause a problem.

Both the previous choices would probably be configured for testability.

Then, along fine-grain pipeline stages, the clock-gated logic gate idea could be used when scanability is not vital. Finally, gated interconnect circuits could be inserted to normalise path delay variation (from different logic state routes through the path).

Pipelined buffer [See included material]

Why these would be used in the overall system—explain.

Misc Circuits

Wave shaping using multiphase rotary clock capacitively driving a single point [capacitor_array_waveshaping.ps] Need arises to make a less than sharp square edge when driving adiabatic or energy recovering logic circuit. The aforementioned diagram gives simple method of using multiphase tap points to create a capacitive divider effect. Using different size capacitors can tailor the waveshape. Ratio of total array capacitance vs. load (to-ground) capacitance determines amplitude of the final wave.
Phase locking between Rotary Clocks having other than 3f frequency differences [4phase_f_lock.ps] is a partial circuit giving the general method where a multiphase and low-speed clock and a two-phase high speed rotary clock can be phase locked together using logic gating. Similarities can be seen to the adiabatic frequency divider concept. Noting that 2phase, 4phase distictions are only geometrical connection-point wire routing issues with Rotary clock—since all ‘liquid’ phases are available on every ring.
   SGIG Claim.
Logic circuitry driven by Adiabatic Rotary Clock where interconnect capacitance as well as all logic capacitance becomes an extension of the Rotary Cluck load and energy is therefore recycled.
as above where Nfets only are used.
As above where charge pump sampling cr
   Lightspeed Claim.
(Relates back to the first US division of the 1^{st} clock patent for data transfer mechanism)
   Transmission-line link with self-biased termination with ratio of supply voltage nominally same as the capacitive divisor ratio of the interconnect capacitance to VDD/VSS thereby reducing power supply noise sensitivity.
   Pulsed transmission-line-drive mode to create high-frequency components only and no residual signal between bits permitting high gain with simplifications of no precompensation.
   Similar claims to US division regarding linking it to Rotary clock source at both ends and knowing the phase delay down the wire and choosing possibly 1-of-4 (or more) phases at the receiver to synchronously decode.
   Extension to off-chip signalling using 4 phase oversampling (SERDES—did I ever write that one up?).

An aspect of the present invention teaches the provision of an Adiabatic frequency divider from Rotary Clock.

A further aspect of the present invention provides a Frequency control using distributed digital serial interface driving switched-capacitor load selection to change LC operating frequency of oscillators.

A still further aspect of the present invention provides a Combination of varactor and switched-capacitor control driven be a controller or FSM as described to cover wide range of frequency/phase locking efficiently.

A Synchronous system design methodology (Flow) according to the present invention incorporates the following algorithms and steps:
Clock Scheduling and Retiming (sequential steps or concurrent optimisation) which guides an autoplacement step to deliver the multiphase shedule according to the optimisation on a real chip.
Where synchronous repeaters, latches, or clock gated logic gates are selected driven by multiphase clock to normalise path delay variation and permit more aggressive timing budgets.
A still further aspect of the rpesent invention provides a Logic circuitry driven by Adiabatic Rotary Clock where interconnect capacitance as well as all logic capacitance becomes an extension of the Rotary clock load and energy is therefore recycled. Preferably, Nfets only are used, and in an advantageous development charge pump sampling cr is also used.

The present invention also provides a transmission-line link with self-biased termination with ratio of supply voltage nominally same as the capacitive divisor ratio of the interconnect capacitance to VDD/VSS thereby reducing power supply noise sensitivity, and Pulsed transmission-line-drive mode to create high-frequency components only and no residual signal between bits permitting high gain with simplifications of no precompensation.

Advantageously, the transmission line link is linked to Rotary clock source at both ends and knowing the phase delay down the wire and choosing possibly 1-of-4 (or more) phases at the receiver to synchronously decode.

The arrangement may be Extended to off-chip signalling using 4 phase oversampling.

1. A method of synchronizing a circuit comprising the steps of synchronising the circuit globally using a high-frequency clock signal, further synchronising at multiple lower frequencies by cooperative short-range state machines clocked by the high-frequency clock, amid synchronising the state machines to each other by exchanging rollover signals between them.

2. A method according to claim 1, comprising the further steps of resynchronising of low-speed, high propagation delay signals from Off-chip to create globally simultanous signals using latency and the fact of high-frequency synchronicity coupled to the cooperative state-machines.

3. A method according to claim 1 or claim 2, comprising the further step of phase locking between rotary structure where logical gating produces other than 3f (square-wave-harmonic-series) locking.

4. A method according to claim 3, wherein logical gating produces 2f locking.

5. An electronic circuit synchronized according to the method as claimed in any of the preceding claims

6. A circuit according to claim 3, whereing the circuit is a scan circuit having SRAM-type randon access read/write method.

7. A circuit according to claim 4, further including gated latches.

8. An energy conserving LC clocking system having progressive simultaneous frequency and supply voltage reduction.
